(19) United States
(12) Patent Application Publication
(10) Pub. No.: US 2025/0328462 A1
(43) Pub. Date: Oct. 23, 2025

(54) MEMORY DEVICE AND OPERATION METHOD THEREOF, AND MEMORY SYSTEM AND STORAGE MEDIUM

(71) Applicant: YANGTZE MEMORY TECHNOLOGIES CO., LTD., Wuhan (CN)

(72) Inventor: Yufei FENG, Wuhan (CN)

(21) Appl. No.: 18/796,121

(22) Filed: Aug. 6, 2024

(30) Foreign Application Priority Data
Apr. 19, 2024 (CN) 2024104837822

(51) Int. Cl. G06F 12/02

(52) U.S. Cl. CPC G06F 12/0246

(57) ABSTRACT

A memory device includes: a memory cell array including memory cells each storing m data bits, wherein the m data bits correspond to m pages, and each page corresponds to a plurality of stages of read voltages; and a peripheral circuit coupled with the memory cell array and configured to: receive a first read instruction, wherein the first read instruction includes indicating reading of data on n data bits among the m data bits of the memory cells, wherein m and n both are positive integers, and 1<n<m; and in response to the first read instruction, read data of n pages among the m pages, wherein in the reading process, different pages among the n pages share at least one stage of read voltages.

### CROSS-REFERENCE TO RELATED APPLICATIONS

The present disclosure claims priority to Chinese Patent Application No. 2024104837822, which was filed Apr. 19, 2024, is titled “MEMORY DEVICE AND ITS OPERATING METHOD, MEMORY SYSTEM AND STORAGE MEDIUM,” and is hereby incorporated herein by reference in its entirety.

### TECHNICAL FIELD

Examples of the present disclosure relate to the technical field of semiconductors, and particularly to a memory device and an operation method thereof, and a memory system and a storage medium.

### BACKGROUND

Memory cells in a NAND memory comprise single-level cells storing 1 bit of data and multi-level cells storing at least 2 bits of data. Although the NAND memory having the single-level cells is faster in write speed and higher in reliability, the NAND memory is small in storage capacity and high in cost; and although the NAND memory having the multi-level cells is relatively slower in write speed and relatively lower in reliability, the NAND memory is large in storage capacity and low in cost.

In some applications, the NAND memory is required to have the fast write speed and high reliability of the single-level cell and the large storage capacity and low cost of the multi-level cell.

### SUMMARY

In view of this, examples of the present disclosure provide a memory device and an operation method thereof, and a memory system and a storage medium.

In a first aspect, examples of the present disclosure provide a memory device. The memory device comprises: a memory cell array comprising memory cells each storing m data bits, wherein the m data bits correspond to m pages, and each page corresponds to a plurality of stages of read voltages; and a peripheral circuit coupled with the memory cell array and configured to: receive a first read instruction, wherein the first read instruction comprises indicating reading of data on n data bits among the m data bits of the memory cells, wherein m and n both are positive integers, and 1<n<m; and in response to the first read instruction, read data of n pages among the m pages, wherein in the reading process, different pages among the n pages share at least one stage of read voltages, and for a corresponding page of the different pages, an ith memory state and a (i+1)th memory state or a (i−1)th memory state among 2″ memory states corresponding to the n data bits are distinguished through the shared at least one stage of read voltages, wherein i is a positive integer and 1<i<n.

In some examples, the peripheral circuit is configured to: in the reading process, skip reading of other pages among the m pages other than the n pages, to sequentially read data of each of the n pages in sequence.

In some examples, the peripheral circuit is configured to: read data of a first page among the n pages through the plurality of stages of read voltages corresponding to the first page; and read at least part of data of a second page among the n pages through part of the plurality of stages of read voltages of the first page.

In some examples, the memory cell array comprises memory cells each storing four data bits, and the first read instruction comprises indicating reading of data on a first data bit and a second data bit among the four data bits of the memory cells. The peripheral circuit is configured to: read the data of the first page corresponding to the first data bit through three stages of read voltages corresponding to the first page; and read the data of the second page corresponding to the second data bit through one stage of read voltages or two stages of read voltages among the three stages of read voltages corresponding to the first page.

In some examples, the peripheral circuit comprises a page buffer, and the page buffer comprises a cache latch and a plurality of data latches. The peripheral circuit is configured to: perform a first operation, wherein the first operation comprises respectively saving, in the plurality of data latches, three sensing results corresponding to the three stages of read voltages; perform a second operation, wherein the second operation comprises performing a first logical operation on data saved in each of the plurality of data latches to obtain the data of the first page, and saving the data of the first page in the cache latch; and perform a third operation, wherein the third operation comprises performing a second logical operation on data saved in part of the plurality of data latches to obtain the data of the second page, and saving the data of the second page in the cache latch.

In some examples, the first read instruction comprises a first prefix command, a first read command, and a second read command. The peripheral circuit is configured to: enter a first read mode according to the first prefix command, and determine data bits to be read as the first data bit and the second data bit; according to the first read command, determine that the data of the first page and the data of the second page have been cleared in a write cache; and perform the first operation and the second operation according to a page to be read of the second read command being the first page, or perform the third operation according to the page to be read of the second read command being the second page, and after completing the performing of the third operation, skip reading of data of a third page and data of a fourth page.

In some examples, the second read command comprises a sequential read command and a read end command. The peripheral circuit is configured to: perform the second operation according to a page to be read of the sequential read command being the first page, or perform the third operation according to the page to be read of the sequential read command being the second page, and after completing the performing of the third operation, skip the reading of the data of the third page and the data of the fourth page, and perform reading of the first page in a next loop; and perform the second operation according to an end page of the read end command being the first page, and after completing the performing of the second operation, exit the first read mode, or perform the third operation according to the end page of the read end command being the second page, and after completing the performing of the third operation, exit the first read mode.

In some examples, the memory cell array comprises memory cells each storing four data bits, and the first read instruction comprises indicating reading of data on a first data bit, a second data bit, and a third data bit among the four data bits of the memory cells. The peripheral circuit is configured to: read the data of the first page corresponding to the first data bit through three stages of read voltages corresponding to the first page; read the data of the second page corresponding to the second data bit through part of the three stages of read voltages corresponding to the first page and part of four stages of read voltages corresponding to the second page; and read the data of the third page corresponding to the third data bit through part of the four stages of read voltages corresponding to the second page and part of three stages of read voltages corresponding to the third page.

In some examples, the peripheral circuit is further configured to: before receiving the first read instruction, receive a first write instruction and data to be written, wherein the first write instruction comprises indicating writing of the data to be written to the n data bits among the m data bits of the memory cells; according to the data to be written, determine dummy data on the remaining data bits among the m data bits other than the n data bits; and write the data to be written and the dummy data to the memory cell array.

In some examples, the peripheral circuit is further configured to: receive a second read instruction, wherein the second read instruction comprises indicating reading of data on m data bits among the m data bits of the memory cells; enter a second read mode to read m pages of data among the m pages, wherein in the reading process, different pages among the m pages all employ different stages of read voltages; and after the read is completed, exit the second read mode.

In a second aspect, examples of the present disclosure provide a memory system. The memory system comprises: one or more memory devices as provided in any of the first aspects; and a memory controller coupled to the memory device and configured to control the memory device.

In some examples, the memory system comprises a solid state disk, and the memory device comprises a NAND memory.

In a third aspect, examples of the present disclosure provide an operation method of a memory device. The memory device comprises a memory cell array and a peripheral circuit coupled with the memory cell array; the memory cell array comprises memory cells each storing m data bits, the m data bits correspond to m pages, and each page corresponds to a plurality of stages of read voltages. The operation method comprises: receiving a first read instruction, wherein the first read instruction comprises indicating reading of data on n data bits among the m data bits of the memory cells, wherein m and n both are positive integers, and 1<n<m; and in response to the first read instruction, reading data of n pages among the m pages, wherein in the reading process, different pages among the n pages share at least one stage of read voltages, and for a corresponding page of the different pages, an ith memory state and a (i+1)th memory state or a (i−1)th memory state among 2″ memory states corresponding to the n data bits are distinguished through the shared at least one stage of read voltages, wherein i is a positive integer and 1<i<n.

In some examples, the operation method comprises: in the reading process, skipping reading of other pages among the m pages other than the n pages, to sequentially reading data of each of the n pages in sequence.

In some examples, the operation method comprises: reading data of a first page among the n pages through the plurality of stages of read voltages corresponding to the first page; and reading at least part of data of a second page among the n pages through part of the plurality of stages of read voltages of the first page.

In some examples, the memory cell array comprises memory cells each storing four data bits, and the first read instruction comprises indicating reading of data on a first data bit and a second data bit among the four data bits of the memory cells. The operation method comprises: reading the data of the first page corresponding to the first data bit through three stages of read voltages corresponding to the first page; and reading the data of the second page corresponding to the second data bit through one stage of read voltages or two stages of read voltages among the three stages of read voltages corresponding to the first page.

In some examples, the peripheral circuit comprises a page buffer, and the page buffer comprises a cache latch and a plurality of data latches. The operation method comprises: performing a first operation, wherein the first operation comprises respectively saving, in the plurality of data latches, sensing results corresponding to the three stages of read voltages; performing a second operation, wherein the second operation comprises performing a first logical operation on data saved in each of the plurality of data latches to obtain the data of the first page, and saving the data of the first page in the cache latch; and performing a third operation, wherein the third operation comprises performing a second logical operation on data saved in part of the plurality of data latches to obtain the data of the second page, and saving the data of the second page in the cache latch.

In some examples, the first read instruction comprises a first prefix command, a first read command, and a second read command. The operation method comprises: entering a first read mode according to the first prefix command, and determining data bits to be read as the first data bit and the second data bit; according to the first read command, determining that the data of the first page and the data of the second page have been cleared in a write cache; and performing the first operation and the second operation according to a page to be read of the second read command being the first page, or performing the third operation according to the page to be read of the second read command being the second page, and after completing the performing of the third operation, skipping reading of data of a third page and data of a fourth page.

In some examples, the second read command comprises a sequential read command and a read end command. The operation method comprises: performing the second operation according to a page to be read of the sequential read command being the first page, or performing the third operation according to the page to be read of the sequential read command being the second page, after completing the performing of the third operation, skipping the reading of the data of the third page and the data of the fourth page, and performing reading of the first page in a next loop; and performing the second operation according to an end page of the read end command being the first page, and after completing the performing of the second operation, exiting the first read mode, or performing the third operation according to the end page of the read end command being the second page, and after completing the performing of the third operation, exiting the first read mode.

In some examples, the memory cell array comprises memory cells each storing four data bits, and the first read instruction comprises indicating reading of data on a first data bit, a second data bit, and a third data bit among the four data bits of the memory cells. The operation method comprises: reading the data of the first page corresponding to the first data bit through three stages of read voltages corresponding to the first page; reading the data of the second page corresponding to the second data bit through part of the three stages of read voltages corresponding to the first page and part of four stages of read voltages corresponding to the second page; and reading the data of the third page corresponding to the third data bit through part of the four stages of read voltages corresponding to the second page and part of three stages of read voltages corresponding to the third page.

In some examples, the operation method comprises: before receiving the first read instruction, receiving a first write instruction and data to be written, wherein the first write instruction comprises indicating writing of the data to be written to the n data bits among the m data bits of the memory cells; according to the data to be written, determining dummy data on the remaining data bits among the m data bits other than the n data bits; and writing the data to be written and the dummy data to the memory cell array.

In some examples, the operation method comprises: receiving a second read instruction, wherein the second read instruction comprises indicating reading of data on m data bits among the m data bits of the memory cells; entering a second read mode to read m pages of data among the m pages, wherein in the reading process, different pages among the m pages all employ different stages of read voltages; and after the read is completed, exiting the second read mode.

In a fourth aspect, examples of the present disclosure provide a storage medium. The storage medium stores executable instructions, and when the executable instructions are executed, operations of any one of the operation methods as provided in any of the third aspects may be implemented.

In various examples of the present disclosure, a memory cell with high storage density is used as a memory cell with a low storage density (not including as a single-level cell). For example, a quad-level cell (QLC) serves as a trinary-level cell (TLC) or a multi-level cell (MLC) for use, such that the number of stages of read voltages is simplified, and the number of times of sensing processes is reduced, thereby shortening a read time and improving read efficiency.

### BRIEF DESCRIPTION OF THE DRAWINGS

FIG. 1 is a schematic diagram of an example system having a memory system according to an example of the present disclosure;

FIG. 2A is a schematic diagram of an example memory card having a memory system according to an example of the present disclosure;

FIG. 2B is a schematic diagram of an example solid-state drive having a memory system according to an example of the present disclosure;

FIG. 3 is a schematic diagram of an example memory comprising a peripheral circuit according to an example of the present disclosure;

FIG. 4 is a schematic cross-sectional view of a memory cell array comprising a NAND memory string according to an example of the present disclosure;

FIG. 5 is a schematic diagram of an example memory device comprising a memory cell array and a peripheral circuit according to an example of the present disclosure;

FIG. 6 is a schematic diagram of an example composition structure having a memory system provided by an example of the present disclosure;

FIG. 7 is a schematic diagram of a threshold voltage distribution corresponding to 4 first-type memory bits set by a memory cell comprising 4 memory bits provided by an example of the present disclosure;

FIG. 8 is a schematic diagram of a threshold voltage distribution corresponding to 3 first-type memory bits set by a memory cell comprising 4 memory bits provided by an example of the present disclosure;

FIG. 9 is a schematic diagram of a threshold voltage distribution corresponding to 2 first-type memory bits set by a memory cell comprising 4 memory bits provided by an example of the present disclosure;

FIG. 10 is a schematic diagram of a threshold voltage distribution corresponding to 1 first-type memory bit set by a memory cell comprising 4 memory bits provided by an example of the present disclosure;

FIG. 11 is a schematic diagram of a threshold voltage distribution corresponding to 2 first-type memory bits set by another memory cell comprising 4 memory bits provided by an example of the present disclosure;

FIG. 12 is a schematic diagram of a threshold voltage distribution corresponding to 3 first-type memory bits set by a memory cell comprising 4 memory bits provided by another example of the present disclosure;

FIG. 13 is a schematic diagram of a threshold voltage distribution corresponding to 2 first-type memory bits set by a memory cell comprising 4 memory bits provided by another example of the present disclosure;

FIG. 14 is a schematic diagram of a threshold voltage distribution corresponding to 2 first-type memory bits set by another memory cell comprising 4 memory bits provided by another example of the present disclosure;

FIG. 15A is a schematic structural diagram of a page buffer corresponding to a memory cell having the threshold voltage distribution of FIG. 13;

FIG. 15B is a schematic diagram of a transmission process of storage data in operations of performing a read operation on a memory cell having the threshold voltage distribution of FIG. 13;

FIG. 16 is a sequential cache read sequence corresponding to 2 first-type memory bits set by a memory cell comprising 4 memory bits provided by another example of the present disclosure;

FIG. 17 is a schematic diagram of summary operations of a first read mode and a second read mode corresponding to 2 first-type memory bits set by a memory cell comprising 4 memory bits provided by another example of the present disclosure;

FIG. 18 is a schematic diagram of detailed operations of a first read mode corresponding to 2 first-type memory bits set by a memory cell comprising 4 memory bits provided by another example of the present disclosure; and

FIG. 19 is a schematic diagram of a composition structure of a storage medium provided by examples of the present disclosure.

### DETAILED DESCRIPTION

Example implementations disclosed herein will be described below in more detail with reference to the drawings. Although example implementations are shown in the figures, it is to be understood that, the present disclosure may be implemented by any form without being limited by the example implementations as set forth herein. On the contrary, these implementations are provided for more thorough understanding of the present disclosure, and to fully convey a scope disclosed in the present disclosure to a person skilled in the art.

In the following descriptions, a lot of details are given in order to provide the more thorough understanding of the present disclosure. However, it is apparent to a person skilled in the art that the present disclosure may be implemented without one or more of these details. In other examples, in order to avoid confusion with the present disclosure, some technical features well-known in the field are not described. Namely, all the features of the actual examples are not described here, and well-known functions and structures are not described in detail.

In addition, the drawings are merely schematic illustrations of the present disclosure and are not necessarily drawn to scale. The same reference signs in the drawings denote same or similar portions, and thus detailed descriptions will be omitted. Some of the block diagrams shown in the drawings are functional entities and do not necessarily have to correspond to physically or logically separate entities. These functional entities may be implemented in a software form, or in one or more hardware modules or integrated circuits, or in different networks and/or processor devices and/or microcontroller devices.

The flowcharts shown in the drawings are exemplary descriptions only and are not necessary to comprise all operations. For example, some operations can also be broken down, while others can be combined or partially combined, such that an actual order of execution is likely to change depending on actual situations.

A purpose of the terms used here is only to describe the examples and not as limitation to the present disclosure. As used herein, unless otherwise indicated expressly in the context, “a”, “one” and “the” in a singular form are also intended to include a plural form. It is also to be understood that terms “comprised of” and/or “comprising”, while used in the description, determine the existence of the described features, integers, steps, operations, elements and/or components, but do not exclude the existence of one or more other features, integers, steps, operations, elements, components, and/or groups. As used herein, the term “and/or” includes any and all combinations of related items listed.

A memory device in examples of the present disclosure includes, but is not limited to, a three-dimensional NAND memory. For ease of understanding, the three-dimensional NAND memory is used as an example for description.

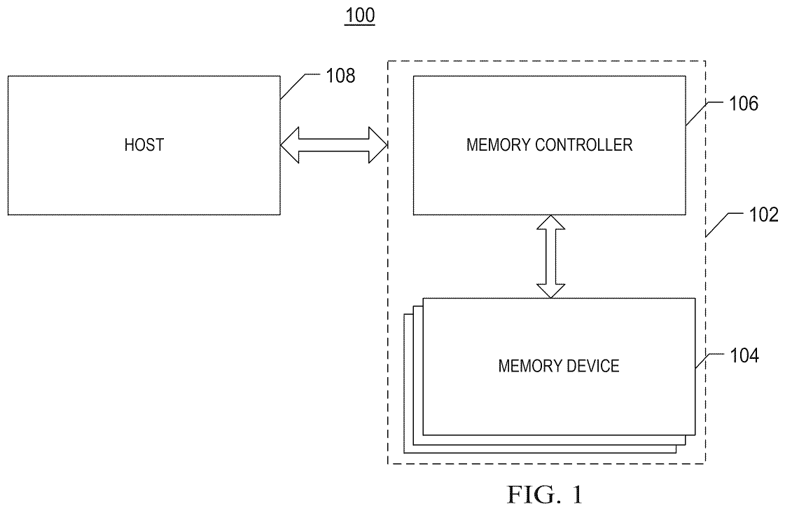

FIG. 1 shows a block diagram of an example system 100 having a memory device according to some aspects of the present disclosure. The system 100 may comprise a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatus having a memory. As shown in FIG. 1, the system 100 may comprise a host 108 and a memory system 102, and the memory system 102 is provided with one or more memory devices 104 and a memory controller 106. The host 108 may be a processor of an electronic apparatus (e.g., a central processing unit (CPU)) or a system on chip (SoC) (such as an application processor (AP)). The host 108 may be configured to send or receive data to or from the memory device 104.

According to some implementations, the memory controller 106 is coupled to the memory device 104 and the host 108, and is configured to control the memory device 104. The memory controller 106 may manage data stored in the memory device 104, and communicate with the host 108. In some implementations, the memory controller 106 is designed for operating in a low duty-loop environment, such as secure digital (SD) cards, compact flash (CF) cards, universal serial bus (USB) flash drives, or other media for use in electronic apparatuses, such as personal computers, digital cameras, mobile phones, etc.

In some implementations, the memory controller 106 is designed for operating in a high duty-loop environment of solid state disks (SSD) or embedded multi-media cards (eMMC) used as data memories for mobile apparatuses, such as smartphones, tablets, laptop computers, etc., and enterprise memory arrays.

The memory controller 106 may be configured to control operations of the memory device 104, such as read, erase, and program operations. The memory controller 106 may further be configured to manage various functions with respect to data stored or to be stored in the memory device 104, including, but not limited to, bad-block management, garbage collection, logical-to-physical address translation, wear leveling, etc. In some implementations, the memory controller 106 is further configured to process error correction codes with respect to the data read from or written to the memory device 104.

The memory controller 106 may further perform any other suitable functions, for example, formatting the memory device 104. The memory controller 106 may communicate with an external apparatus (e.g., the host 108) according to a communication protocol. For example, the memory controller 106 may communicate with the external apparatus through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The memory controller 106 and the one or more memory devices 104 can be integrated into various types of storage apparatuses, for example, be comprised in the same package (such as a universal flash storage (UFS) package or an eMMC package). That is to say, the memory system 102 may be implemented and packaged into different types of end electronic products.

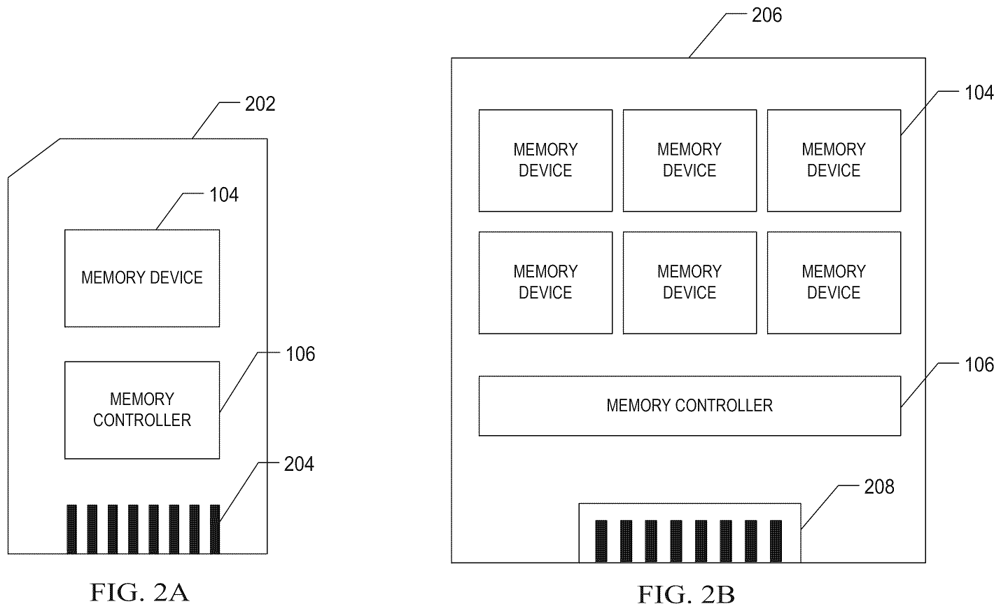

In one example shown in FIG. 2A, the memory controller 106 and the single memory device 104 may be integrated into a memory card 202. The memory card 202 may comprise a personal computer memory card international association (PCMCIA, PC) card, a CF card, a smart media (SM) card, a memory stick, a multimedia card (MMC, RS-MMC, MMCmicro), an SD card (SD, miniSD, microSD, SDHC), a UFS, etc. The memory card 202 may further comprise a memory card connector 204 coupling the memory card 202 with a host (e.g., the host 108 in FIG. 1).

In another example as shown in FIG. 2B, the memory controller 106 and the plurality of memory devices 104 may be integrated into an SSD 206. The SSD 206 may further comprise an SSD connector 208 coupling the SSD 206 with the host (e.g., the host 108 in FIG. 1). In some implementations, at least one of a storage capacity or an operation speed of the SSD 206 is greater than at least one of a storage capacity and/or an operation speed of the memory card 202.

In some examples, each memory block may be coupled with a plurality of word lines, and a plurality of memory cells coupled with each word line constitute a physical page.

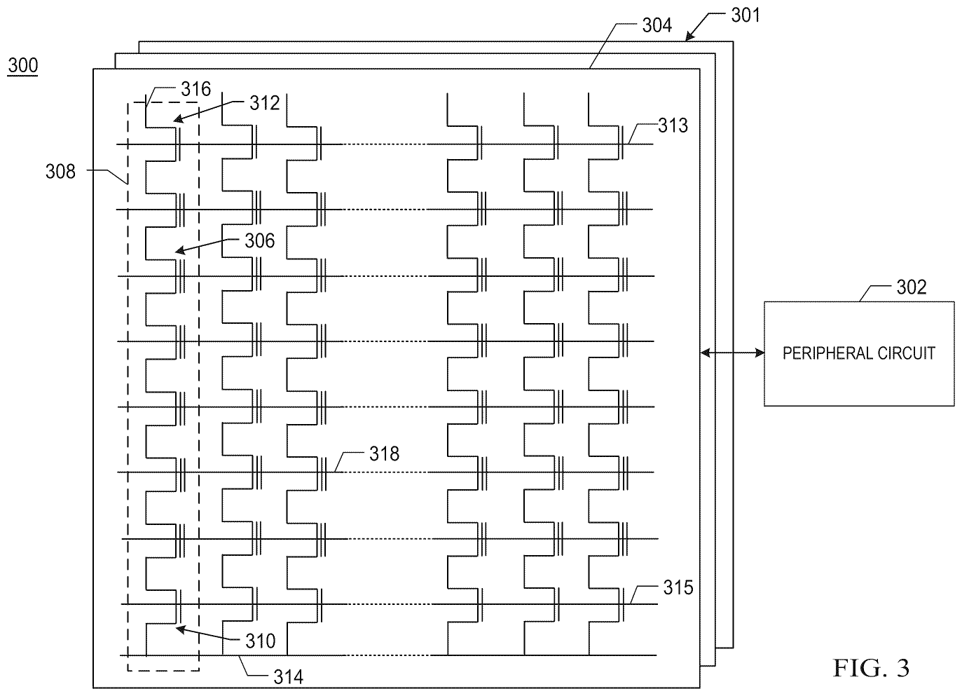

FIG. 3 shows a schematic circuit diagram of an example memory device 300 comprising a peripheral circuit according to some aspects of the present disclosure. The memory device 300 may be an example of the memory device 104 in FIG. 1. The memory device 300 may comprise a memory cell array 301 and a peripheral circuit 302 coupled to the memory cell array 301. For example, the memory cell array 301 is a three-dimensional NAND memory array, wherein a memory cell 306 is a NAND memory cell; the memory cell 306 is provided in the form of an array of memory strings 308; and each memory string 308 extends vertically above a substrate (not shown). In some implementations, each memory string 308 may comprise a plurality of memory cells 306 coupled in series and stacked vertically. Each memory cell 306 may maintain a continuous analog value, such as voltage or charge, which depends on the number of electrons trapped within a region of the memory cells 306. Each memory cell 306 may be either a floating gate type memory cell comprising a floating gate transistor, or a charge trapping type memory cell comprising a charge trapping transistor.

In some implementations, each memory cell 306 is a single-level cell (SLC) that has two possible memory states and thus may store one bit of data. For example, a first memory state “0” may correspond to a first voltage range, and a second memory state “1” may correspond to a second voltage range. In some implementations, each memory cell 306 is a multi-level cell (MLC) that can store more than one bit of data in more than four memory states. For example, the MLC can store two bits per cell (which may also be called a double-level cell), three bits per cell (also called a trinary-level cell (TLC)), four bits per cell (also called a quad-level cell (QLC)), five bits per cell (also called a penta-level cell (PLC)), or more than five bits per cell. Each MLC can be programmed to assume a range of possible nominal storage values. In one example, if each MLC stores two bits of data, the MLC can be programmed to employ one of three possible programmed levels from an erased state by writing one of three possible nominal storage values to the cell, and a fourth nominal storage value may be used for the erased state.

It is to be noted that, the memory state described here is the memory state of a memory cell described in the present disclosure. Different memory cells have different numbers of memory states. For example, a SLC-type memory cell has 2 memory states (e.g., two states of memory), wherein the 2 memory states comprise one programmed state and one erased state. For another example, a MLC-type memory cell has 4 memory states, wherein the 4 memory states comprise one erased state and three programmed states. For yet another example, a TLC-type memory cell has 8 memory states, wherein the 8 memory states comprise one erased state and seven programmed states. In some implementations, a QLC-type memory cell has 16 memory states, wherein the 16 memory states comprise one erased state and fifteen programmed states.

As shown in FIG. 3, each memory string 308 may comprise a bottom select transistor 310 (BSG, also referred to as a source side select transistor) at a source terminal of the memory string and a top select transistor 312 (TSG, also referred to as a drain side select transistor) at a drain terminal of the memory string. The BSG 310 and the TSG 312 may be configured to activate a selected memory string 308 during read and program operations. In some implementations, sources of memory strings 308 in a same memory block 304 are coupled through a same source line (SL) 314 (e.g., a common SL). For example, according to some implementations, all the memory strings 308 in the same memory block 304 have an array common source (ACS). According to some implementations, the TSG 312 of each memory string 308 is coupled to a respective bit line (BL) 316, and data may be read or written from the bit line 316 via an output bus (not shown). In some implementations, each memory string 308 is configured to be selected or unselected by applying a select voltage (e.g., above a threshold voltage of a transistor having the TSG 312) or an unselect voltage (e.g., 0 V) to the respective TSG 312 via one or more TSG lines 313 and/or by applying a select voltage (e.g., above a threshold voltage of a transistor having the BSG 310) or an unselect voltage (e.g., 0 V) to the respective BSG 310 via one or more BSG lines 315.

As shown in FIG. 3, the memory strings 308 may be organized into a plurality of memory blocks 304, and each of the plurality of memory blocks 304 may have a common source line 314 (e.g., coupled to the ground). In some implementations, each memory block 304 is a basic data unit for an erase operation, e.g., all of the memory cells 306 on the same memory block 304 are erased at the same time. In order to erase the memory cells 306 in a selected memory block 304, the source lines 314 coupled to the selected memory block 304 as well as unselected memory blocks 304 that are in the same plane as the selected memory block 304 can be biased with an erase voltage (Vers, such as a high positive voltage (e.g., 20 V or higher)). It is to be understood that in some examples, the erase operation may be performed at a half memory block level, a quarter memory block level, or a level having any suitable number of memory blocks or any suitable fractions of a memory block. The memory cells 306 of adjacent ones of the memory strings 308 may be coupled through word lines 318 that select which row of memory cells 306 is affected by the read and program operations.

Referring to FIG. 3, each of the plurality of memory cells 306 is coupled to a respective word line 318, and each memory string 308 is coupled to the respective bit line 316 through a respective select transistor (such as, the top select transistor (TSG) 312).

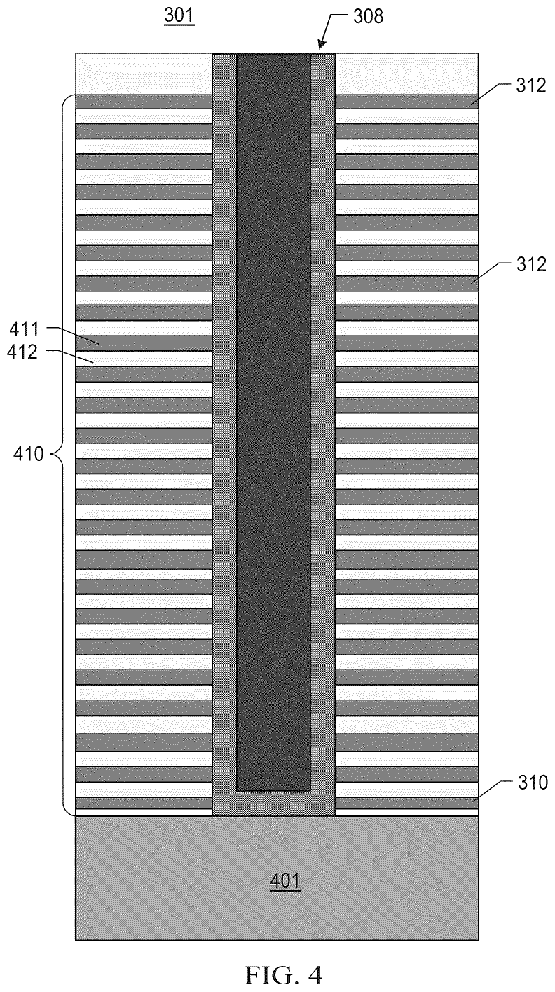

FIG. 4 shows a schematic cross-sectional view of an example memory cell array 301 comprising a memory string 308 which takes NAND as an example according to some aspects of the present disclosure. As shown in FIG. 4, the NAND memory cell array 301 may comprise a stack structure 410. The stack structure 410 comprises a plurality of gate layers 411 and a plurality of insulation layers 412 that are sequentially and alternately stacked and a channel structure that runs through the gate layers 411 and the insulation layers 412 vertically. The channel structure is coupled with each gate layer to form a memory cell. The channel structure is coupled with the plurality of gate layers in the stack structure 410 to form the memory string 308. The gate layers 411 and the insulation layers 412 may be alternately stacked, and two adjacent gate layers 411 are spaced apart by one insulation layer 412.

A constituent material of the gate layers 411 may comprise a conductive material. The conductive material includes, but is not limited to, tungsten (W), cobalt (Co), copper (Cu), aluminum (Al), polysilicon, doped silicon, silicides, or any combination thereof. In some implementations, each gate layer 411 comprises a metal layer, e.g., a tungsten layer. In some implementations, each gate layer 411 comprises a doped polysilicon layer. Each gate layer 411 may comprise a control gate surrounding the memory cells. The gate layer 411 at the top of the stack structure 410 may extend laterally as a top select gate line; the gate layer 411 at the bottom of the stack structure 410 may extend laterally as a bottom select gate line; and the gate layers 411 that extend laterally between the top select gate line and the bottom select gate line may act as word line layers.

In some examples, the stack structure 410 may be disposed on a substrate 401. The substrate 401 may comprise silicon (e.g., single crystalline silicon), silicon germanium (SiGe), gallium arsenide (GaAs), germanium (Ge), silicon on insulator (SOI), germanium on insulator (GOI), or any other suitable materials.

In some examples, a memory string 308 comprises a channel structure that extends through the stack structure 410 vertically. In some implementations, the channel structure comprises a channel hole filled with (one or more) semiconductor materials (e.g., as a semiconductor channel) and (one or more) dielectric materials (e.g., as a memory film). In some implementations, the semiconductor channel comprises silicon, e.g., polysilicon. In some implementations, the memory film is a composite dielectric layer comprising a tunneling layer, a storage layer (also referred to as a “charge trapping/storage layer”), and a blocking layer. The channel structure may have a cylindrical shape (e.g., a pillar shape). According to some implementations, the semiconductor channel, the tunneling layer, the storage layer, and the blocking layer are arranged radially from the center toward the outer surface of the pillar in this order. The tunneling layer may comprise silicon oxide, silicon oxynitride, or any combination thereof. The storage layer may comprise silicon nitride, silicon oxynitride, or any combination thereof. The blocking layer may comprise silicon oxide, silicon oxynitride, a high dielectric constant (high-k) dielectric, or any combination thereof. In one example, the memory film may comprise a composite layer of silicon oxide/silicon oxynitride/silicon oxide (ONO).

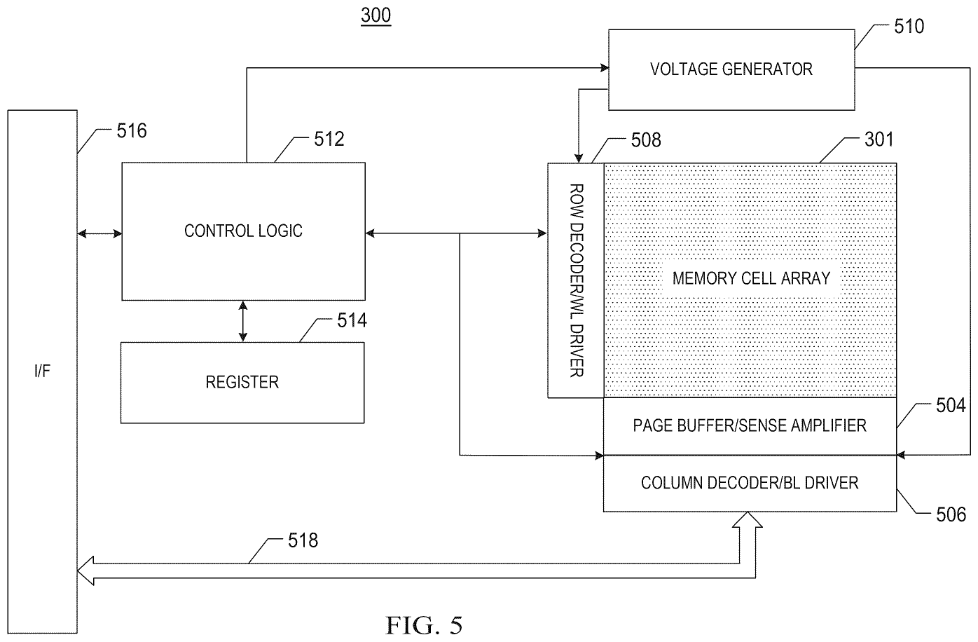

Referring back to FIG. 3, the peripheral circuit 302 may be coupled to the memory cell array 301 through the bit line 316, the word line 318, the source line 314, the BSG line 315, and the TSG line 313. The peripheral circuit 302 may comprise any suitable analog, digital, and hybrid signal circuits for facilitate the operations of the memory cell array 301 by applying and sensing at least one of voltage signals or current signals to and from each target memory cell 306 via bit lines 316, word lines 318, the source line 314, the BSG line 315, and the TSG line 313. The peripheral circuit 302 may comprise various types of peripheral circuits formed using a metal-oxide-semiconductor (MOS) technology. For example, FIG. 5 shows some example peripheral circuits. The peripheral circuit comprises a page buffer/sense amplifier 504, a column decoder/bit line driver 506, a row decoder/word line driver 508, a voltage generator 510, a control logic 512, a register 514, an interface 516, and a data bus 518. It is to be understood that, in some examples, additional peripheral circuits not shown in FIG. 5 may also be comprised as well.

The page buffer/sense amplifier 504 may be configured to read and program (write) data from and to the memory cell array 301 according to a control signal from the control logic 512. In one example, the page buffer/sense amplifier 504 may store program data (write data) to be programmed into the memory cell array 301. In another example, the page buffer/sense amplifier 504 may execute a program verification operation to ensure that the data has been properly programmed into the memory cell 306 coupled to the selected word line 318. In yet another example, the page buffer/sense amplifier 504 may also sense a low power signal from the bit line 316 that represents a data bit stored in the memory cell 306, and amplifies a small voltage swing to a recognizable logic level in the read operation. The column decoder/bit line driver 506 may be configured to be controlled by the control logic 512 and select one or more memory strings 308 by applying a bit line voltage acquired from the voltage generator 510.

The row decoder/word line driver 508 may be configured to be controlled by the control logic 512, select/unselect the memory blocks 304 of the memory cell array 301, and select/unselect the word lines 318 of the memory blocks 304. The row decoder/word line driver 508 may be further configured to drive the word lines 318 using a word line voltage acquired from the voltage generator 510. In some implementations, the row decoder/word line driver 508 may also select/unselect and drive the BSG line 315 and the TSG line 313. As described below in detail, the row decoder/word line driver 508 is configured to perform the program operation on the memory cells 306 coupled to (one or more) selected word lines 318. The voltage generator 510 may be configured to be controlled by the control logic 512 and acquire the word line voltage (such as, a read voltage, a program voltage, a pass voltage, a channel boost voltage, a verify voltage, etc.), the bit line voltage, and a source line voltage to be supplied to the memory cell array 301.

The control logic 512 can be coupled to every other portion in the peripheral circuit described above and configured to control the operations of every other portion in the peripheral circuit. The register 514 may be coupled to the control logic 512 and comprise a state register, a command register, and an address register for storing state information, a command operation code (OP code), and a command address for controlling the operations of each peripheral circuit. The interface 516 may be coupled to the control logic 512, and act as a control buffer to buffer and relay control commands received from a host (not shown) to the control logic 512, and buffer and relay the state information received from the control logic 512 to the host. The interface 516 may also be coupled to the column decoder/bit line driver 506 via the data bus 518 and act as a data I/O interface and a data buffer to buffer and relay the data to and from the memory cell array 301.

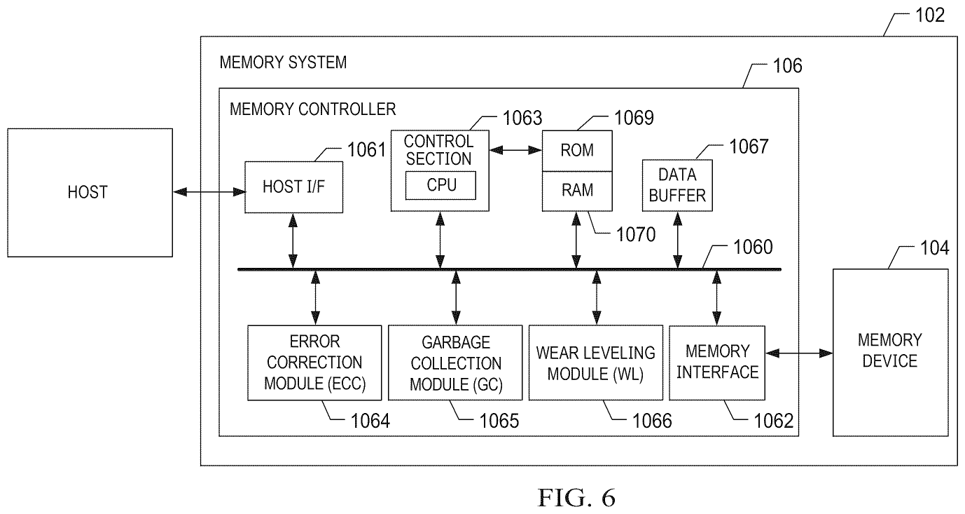

Referring to FIG. 6, in some examples, the memory system 102 is coupled with a host, and performs a variety of feedbacks in response to instructions of the host. The memory system 102 may comprise the memory controller 106 and the memory device 104, wherein the memory controller 106 is configured to control the memory device 104 to perform operations of read, write, erase, etc.; and the memory controller 106 and the memory device 104 may also be coupled in any suitable manner.

The memory controller 106 may comprise a host interface (I/F) 1061, a memory interface (I/F) 1062, a processor 1063 (which may also be referred to as a control section), a read-only memory (ROM) 1069, a random access memory (RAM) 1070, an error correcting module 1064, a garbage collection module 1065, a wear leveling module 1066, a data buffer 1067, and a bus 1060. The host interface 1061 is a connection interface connecting the host 108 and the memory controller 106; and the host interface 1061 allows the host 108 and the memory controller 106 to communicate according to a protocol, send read and write requests, and perform other operations. The memory interface 1062 is a connection interface between the memory controller 106 and the memory device 104; and the memory interface 1062 is configured to achieve data transmission between the memory controller 106 and the memory device 104. The processor 1063 is configured to entirely control the memory system 102, and the aforementioned operations performed by the memory controller 106 are mainly performed and completed by the processor 1063 here. In some examples, the processor 1063 is, for example, a central processing unit (CPU), a micro-processing unit (MCU), etc. The ROM 1069 usually comprises firmware or firmware program codes of the memory controller 106. These codes are used for initializing and operating various components of the memory controller 106, and the RAM 1070 is usually configured to buffer data. The error correction module 1064 may further comprise an encoding section and a decoding section. The encoding section is configured to encode data to be stored, so as to obtain check data, and the decoding section is configured to decode the check data to detect and correct possible error data in a process of data transmission.

The garbage collection module 1065 is configured to: after a memory space of the memory device reaches a certain threshold, read out valid data in some memory blocks, perform rewrite, and then label these memory blocks, to obtain new spare memory blocks. A general implementation of garbage collection may comprise three operations: selecting a source memory block with a small amount of valid data; finding the valid data from the source memory block; and writing the valid data to a target memory block. In this case, all data in the source memory block becomes invalid data; and the source memory block is labeled, and may be used as a new spare memory block. The wear leveling module 1066 is configured to level wear (a number of erase times) of each memory block in the memory system 102 through data statistics and algorithms. A general implementation of wear leveling may comprise two operations: selecting a source memory block in which cold data is located; and reading valid data in the source memory block and writing the same to a memory block with a relatively large number of erase times. In this case, the valid data in the source memory block becomes invalid data, and the source memory block is labeled. The data buffer 1067 is configured to buffer data.

In a NAND memory, because of the advantages of being fast in read-write speed, high in reliability, and long in service life, a single-level cell (SLC) occupies a certain share of the memory market; and because of higher storage density and larger storage capacities, a multi-level cell (MLC), a trinary-level cell (TLC), and a quad-level cell (QLC) become a development trend of the memory market.

In some examples, a memory cell with high storage density may be used as a memory cell with low storage density, e.g., a plurality of bits of memory cells are backward compatible for use. In an example, the quad-level cell (QLC) serves as the single-level cell (SLC), the multi-level cell (MLC), or the trinary-level cell (TLC) for use. It can be understood that, each quad-level cell comprises four memory bits (which may also be referred to as “data bits”), in a process of performing the above-mentioned solution, part of the four memory bits are configured to store valid data, and the remaining memory bits store redundant data, wherein the redundant data may be designated/fixed data, such as 1 or 0, etc., or a logical operation performed on the valid data, etc.; and these redundant data are generally discarded or not fully utilized during usage of the memory.

In some examples, the memory cell array comprises memory cells each storing m data bits, wherein the memory cells of m data bits read data of the m data bits through P-stage read voltages; the m data bits correspond to m pages, and each page reads data of the page through Q-stage read voltages; and P and Q are integers greater than 1, and P=2^{m}−1, Q≤m.

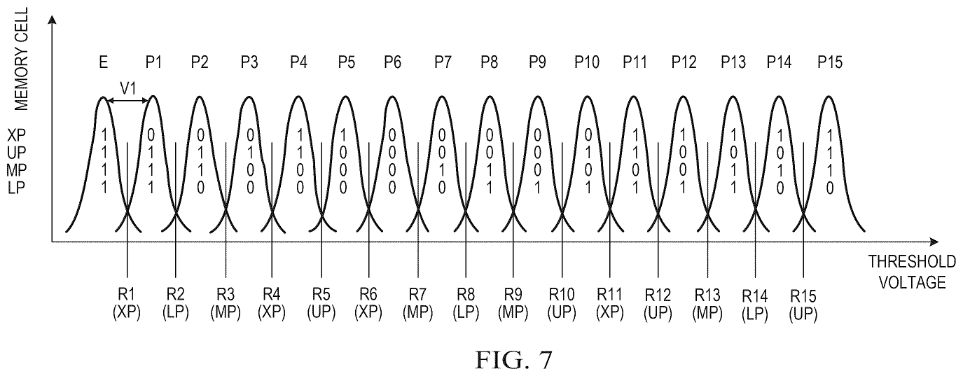

Referring to FIG. 7, a memory cell comprises four memory bits, and corresponding memory states comprise a 0th state to 15th state, which respectively are the 0th state E (also referred to as an erased state), the 1st state P1 (also referred to as a 1st memory state), the 2nd state P2 (also referred to as a 2nd memory state), . . . , and the 15th state P15 (also referred to as a 15th memory state); a read margin/window between two adjacent states is a first margin V1; and binary data corresponding to the 16 states is 1111, 0111, 0110, . . . , 1110, respectively. Meanwhile, for each memory bit in the selected 16 states, 16 pieces of binary data corresponding to first memory bits LP are 1100000011111100, 16 pieces of binary data corresponding to second memory bits MP are 1110000110000111, 16 pieces of binary data corresponding to third memory bits UP are 1111100000110001, and 16 pieces of binary data corresponding to fourth memory bits XP are 1000110000011111. Herein, the four memory bits corresponding to the 16 states respectively are the first memory bits LP, the second memory bits MP, the third memory bits UP, and the fourth memory bits XP. Four pages respectively are a lower page (LP), a middle page, an upper page, and an extra page. Data of the four data bits is stored in the lower page, the middle page, the upper page, and the extra page, respectively.

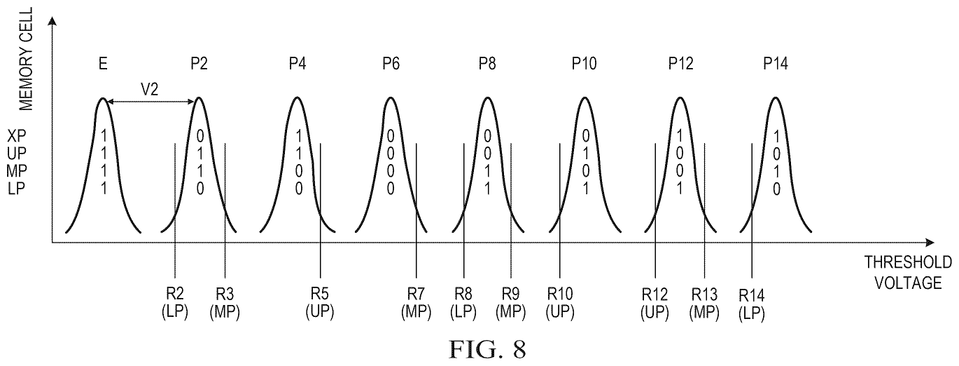

Referring to FIGS. 7 and 8, when a quad-level cell serves as a trinary-level cell for use, the valid data is stored in the first memory bits LP, the second memory bits MP, and the third memory bits UP, and check data is stored in the fourth memory bits XP, wherein four pieces of binary data constituted by the valid data and the check data respectively are the same as binary data corresponding to the 0th state E, the 2nd state P2, the 4th state P4, the 6th state P6, the 8th state P8, the 10th state P10, the 12th state P12, and the 14th state P14. Meanwhile, for each memory bit in the selected 8 states, 8 pieces of binary data corresponding to the first memory bits LP are 10001110, 8 pieces of binary data corresponding to the second memory bits MP are 11001001, 8 pieces of binary data corresponding to the third memory bits UP are 11100100, and 8 pieces of binary data corresponding to the fourth memory bits XP are 10100011. When the quad-level cell serves as the trinary-level cell for use, a read margin/window between two adjacent states of the trinary-level cell is a second margin V2, and the second margin V2 is greater than the first margin V1.

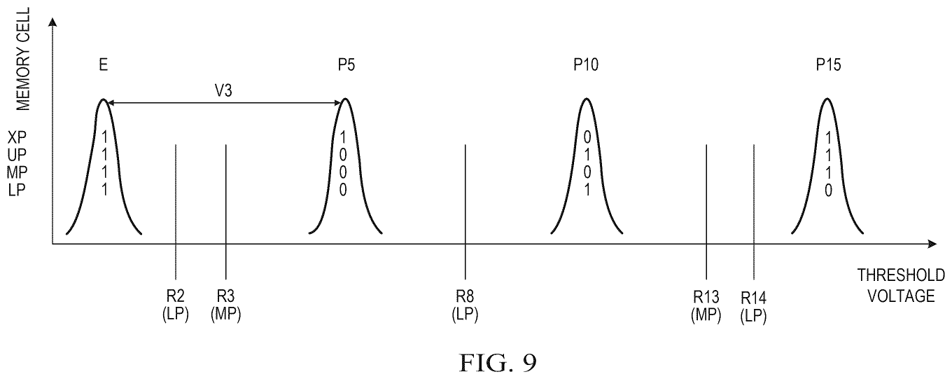

Referring to FIGS. 7 and 9, when the quad-level cell serves as the multi-level cell for use, the valid data is stored in the first memory bits LP and the second memory bits MP, and the check data is stored in the third memory bits UP and the fourth memory bits XP, wherein the four pieces of binary data constituted by the valid data and the check data respectively are the same as binary data corresponding to the 0th state E, the 5th state P5, the 10th state P10, and the 15th state P15. Meanwhile, for each memory bit in the selected 4 states, 4 pieces of binary data corresponding to the first memory bits LP are 1010, 4 pieces of binary data corresponding to the second memory bits MP are 1001, 4 pieces of binary data corresponding to the third memory bits UP are 1011, and 4 pieces of binary data corresponding to the fourth memory bits XP are 1101. When the quad-level cell serves as the multi-level cell for use, a read margin/window between two adjacent states is a third margin V3, and the third margin V3 is greater than the first margin V1.

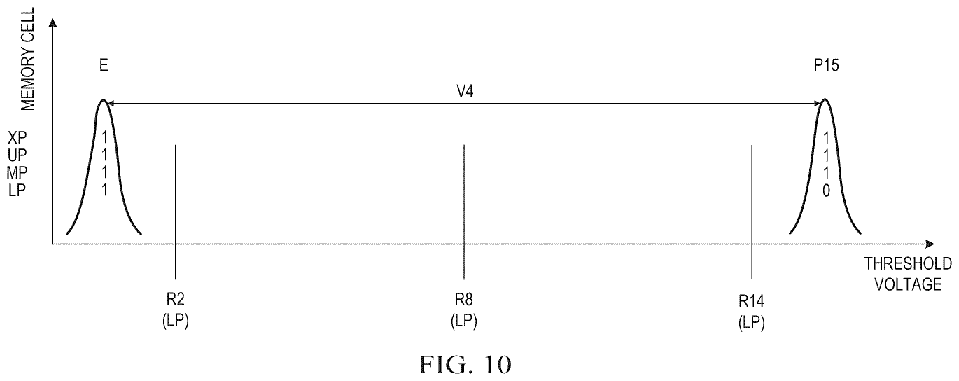

Referring to FIGS. 7 and 10, when the quad-level cell serves as the single-level cell for use, the valid data is stored in the first memory bits LP, and the check data is stored in the second memory bits MP, the third memory bits UP, and the fourth memory bits XP, wherein the four pieces of binary data constituted by the valid data and the check data respectively are the same as binary data corresponding to the 0th state E and the 15th state P15. It is to be noted that, the four pieces of binary data constituted by the valid data and the check data may also be the same as binary data corresponding to other states, for example, the 0th state and the 8th state P8. Meanwhile, for each memory bit in the selected 2 states, 2 pieces of binary data corresponding to the first memory bits LP are 10, and 2 pieces of binary data corresponding to the second memory bits MP, the third memory bits UP, and the fourth memory bits XP are all 11.

Referring to FIGS. 7 and 10, when the quad-level cell serves as the single-level cell for use, a read margin/window between two adjacent states is a fourth margin V4, and the fourth margin V4 is greater than the first margin V1.

The lower page is generally the closest to a source/drain, such that preferably determining each of the corresponding stages of read voltages of the lower page has the fastest access speed and shortest response time, and can guarantee the balance performance and durability during a data access process.

It is to be noted that, the manner of preferably determining each of the corresponding stages of read voltages of the lower page is only an example, and is not used to limit a determination sequence of each of the plurality of stages of read voltages corresponding to at least part of the pages in the examples of the present disclosure.

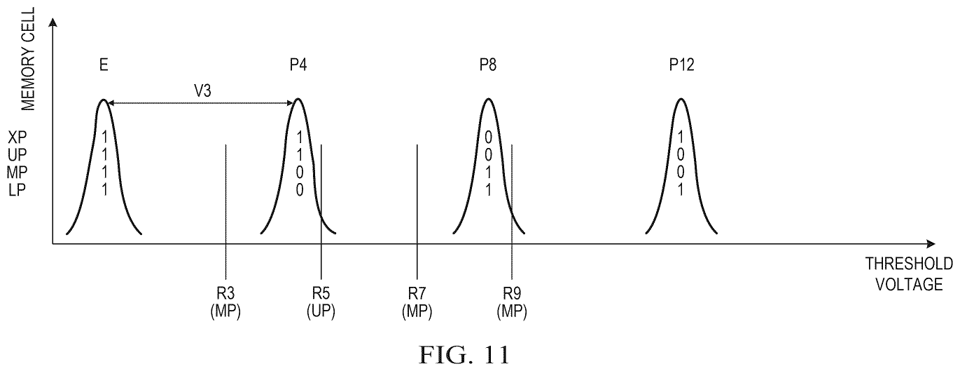

Referring to FIGS. 7 and 11, when a quad-level cell serves as another type of multi-level cell for use, the valid data may be stored in the second memory bits MP and the third memory bits UP, and the check data is stored in the first memory bits LP and the fourth memory bits XP, wherein the four pieces of binary data constituted by the valid data and the check data respectively are the same as binary data corresponding to the 0th state E, the 4th state P4, the 8th state P8, and the 12th state P12. Meanwhile, for each memory bit in the selected 4 states, 4 pieces of binary data corresponding to the first memory bits LP are 1011, 4 pieces of binary data corresponding to the second memory bits MP are 1010, 4 pieces of binary data corresponding to the third memory bits UP are 1100, and 4 pieces of binary data corresponding to the fourth memory bits XP are 1101. When the quad-level cell serves as the multi-level cell for use, the read margin/window between two adjacent states is the third margin V3, and the third margin V3 is greater than the first margin V1.

It can be understood that, when the plurality of bits of memory cells are backward compatible for use, due to the reduction of the number of threshold voltage (Vt) distributions, a single read window range is broadened, and due to the reduction of the number of threshold voltage (Vt) distributions, the number of read windows generating error bits is reduced. Meanwhile, in a practical application, the error bits are gradually generated with the usage of a memory system (problems with retention or read disturbance are seen from the perspective of a system terminal), check errors (UNC, also referred to as ECC errors) may initially appear in one page in the lower page/middle page/upper page/extra page only (based on the aforementioned two facts that the single read window range is broadened and the number of read windows generating error bits is reduced, the probability that a single page is unable to be corrected (UNC) is higher than that of a normal QLC), there may be a higher number of errors on other pages, but the errors can also be successfully corrected through a Low Density Parity Check Code (LDPC). If refresh is not performed currently, as the error bits on other pages slowly increase, other pages may also become UNCs. Based on this, when the plurality of bits of memory cells are backward compatible for use, the redundant data may be used as a kind of check data.

Referring to FIGS. 7 and 8, in an example, when the quad-level cell serves as the trinary-level cell for use, after eight states corresponding to the trinary-level cell are determined, the valid data may be stored in the first memory bits LP, the second memory bits MP, and the third memory bits UP according to actual requirements; furthermore, since the binary data constituted by the valid data and the check data is the same as binary data corresponding to one memory state of the memory cell, the check data currently stored in the fourth memory bits XP is also a determined value. In this case, a correspondence relationship between the fourth memory bits XP and the first memory bits LP, the second memory bits MP, and the third memory bits UP may be determined according to derivation.

In an example, from derivation, it can be learned that the fourth memory bits XP is obtained by performing an exclusive OR operation on the first memory bits LP, the second memory bits MP, and the third memory bits UP respectively (an operator of the exclusive OR operation is XOR or is represented by “\hat{ }”), and a corresponding expression is: XP=UP XOR MP XOR LP.

It is to be noted that, the exclusive OR operation is one of basic logical operations; in binary, if two binary numbers in a same position are the same, a result is “0”; and if the two binary numbers in the same position are different, the result is “1” (e.g., the same is 0, and the different is 1). Herein, different states corresponding to each memory bit need to be operated respectively.

Referring to FIGS. 7 and 9, in an example, when the quad-level cell serves as the multi-level cell for use, after four states corresponding to the multi-level cell are determined, the valid data may be stored in the first memory bits LP and the second memory bits MP according to actual requirements; furthermore, since the binary data constituted by the valid data and the check data is the same as the binary data corresponding to one memory state of the memory cell, data currently stored in the third memory bits UP and the fourth memory bits XP is also a determined value. In this case, a correspondence relationship between the third memory bits UP and the fourth memory bits, respectively, and the first memory bits LP and the second memory bits MP may be determined according to derivation.

In an example, from derivation, it can be learned that the third memory bits UP is obtained by performing an OR operation on the first memory bits LP and the second memory bits MP (an operator of the OR operation is represented by using “OR” or “|”), and a corresponding expression is UP=LP OR MP; and the fourth memory bits XP may be obtained by performing a NOT operation on the first memory bits LP (an operator of the not operation is represented by using “NOT” or “˜”), and then performing the OR operation with the second memory bits MP, and a corresponding expression is XP=(˜LP) OR MP. Herein, different states corresponding to each memory bit need to be operated respectively.

It is to be noted that, the OR operation is also referred to logical OR and is one of basic logical operations; in binary, for two binary numbers at a same position, if there is a “1”, the result is “1”, otherwise is “0” (e.g., if there is a 1 then result is 1, and if both 0, then 0).

Referring to FIGS. 7 and 11, in an example, when the quad-level cell serves as another multi-level cell for use, after four states corresponding to the multi-level cell are determined, the valid data may be stored in the second memory bits MP and the third memory bits UP according to actual requirements; furthermore, since the binary data constituted by the valid data and the check data is the same as the binary data corresponding to one memory state of the memory cell, the data currently stored in the first memory bits LP and the fourth memory bits XP is also a determined value. In this case, a correspondence relationship between the first memory bits LP and the fourth memory bits XP, respectively, and the second memory bits MP and the third memory bits UP may be determined according to derivation.

In an example, from derivation, it can be learned that the first memory bits LP is obtained by performing the NOT operation on the third memory bits UP, and then performing the OR operation with the second memory bits MP, and a corresponding expression is UP=MP OR (˜UP); and the fourth memory bits XP may be obtained by performing the NOT operation on the second memory bits MP, and then performing the OR operation with the third memory bits UP, and a corresponding expression is XP=UP OR (˜MP). Herein, different states corresponding to each memory bit need to be operated respectively.

Referring to FIGS. 7 and 10, in an example, when the quad-level cell serves as the single-level cell for use, after two states corresponding to the single-level cell are determined, the valid data may be stored in the first memory bits LP according to actual requirements; furthermore, since the binary data constituted by the valid data and the check data is the same as the binary data corresponding to one memory state of the memory cell, the check data currently stored in the second memory bits MP, the third memory bits UP, and the fourth memory bits XP is also a determined value. In this case, a correspondence relationship between the second memory bits MP, the third memory bits UP, and the fourth memory bits XP, respectively, and the first memory bits LP may be determined according to derivation.

In an example, from derivation, it can be learned that the second memory bits MP is obtained by performing the NOT operation on the first memory bits LP, and then performing the OR operation with the first memory bits LP, and a corresponding expression is MP=(˜LP) OR LP; and an expression corresponding to the third memory bits UP and an expression corresponding to the fourth memory bits XP are the same as an expression corresponding to the second memory bits MP.

It is to be noted that, since the valid data is stored in only the first memory bits LP in the single-level cell, various expressions exist between the first memory bits LP and the second memory bits MP, the third memory bits UP, and the fourth memory bits XP, respectively, and details are not described herein again.

Referring to FIG. 7, the quad-level cell may read four-bit sixteen-state storage data through 15 stages of read voltages. Sixteen-bit binary data corresponding to the lower page is 1100000011111100, and reading the lower page needs a second-stage read voltage R2, an eighth-stage read voltage R8, and a fourteenth-stage read voltage R14. Sixteen-bit binary data corresponding to the middle page is 1110000110000111, and reading the middle page needs a third-stage read voltage R3, a seventh-stage read voltage R7, a ninth-stage read voltage R9, and a thirteenth-stage read voltage R13. Sixteen-bit binary data corresponding to the upper page is 1111100000110001, and reading the upper page needs a fifth-stage read voltage R5, a tenth-stage read voltage R10, a twelfth-stage read voltage R12, and a fifteenth-stage read voltage R15. Sixteen-bit binary data corresponding to the extra page is 1000110000011111, and reading the extra page needs a first-stage read voltage R1, a fourth-stage read voltage R4, a sixth-stage read voltage R6, and an eleventh-stage read voltage R11.

Referring to FIG. 8, in an example, the quad-level cell serves as the trinary-level cell for use, and may read three-bit eight-state storage data through 10 stages of read voltages. Eight-bit binary data corresponding to the lower page is 10001110, and reading the lower page needs the second-stage read voltage R2, the eighth-stage read voltage R8, and the fourteenth-stage read voltage R14. Eight-bit binary data corresponding to the middle page is 11001001, and reading the middle page needs the third-stage read voltage R3, the seventh-stage read voltage R7, the ninth-stage read voltage R9, and the thirteenth-stage read voltage R13. Eight-bit binary data corresponding to the upper page is 11100100, and reading the upper page needs the fifth-stage read voltage R5, the tenth-stage read voltage R10, and the twelfth-stage read voltage R12. Eight-bit binary data corresponding to the extra page is 10100011, and the binary data corresponding to the extra page is used as the check data, and may skip the reading of the data of the extra page.

Referring to FIG. 9, in an example, the quad-level cell serves as the trinary-level cell for use, and may read two-bit four-state storage data through 5 stages of read voltages. Four-bit binary data corresponding to the lower page is 1010, and reading the lower page needs the second-stage read voltage R2, the eighth-stage read voltage R8, and the fourteenth-stage read voltage R14. Four-bit binary data corresponding to the middle page is 1001, and reading the middle page needs the third-stage read voltage R3 and the thirteenth-stage read voltage R13. Four-bit binary data corresponding to the upper page is 1011, four-bit binary data corresponding to the extra page is 1101, and the binary data corresponding to the upper page and the extra page is used as the check data, and may skip the reading of the data of the upper page and the extra page.

Referring to FIG. 10, in an example, the quad-level cell serves as the single-level cell for use, and may read one-bit two-state storage data through one stage of read voltages. Two-bit binary data corresponding to the lower page is 10, and reading the lower page needs the second-stage read voltage R2, the eighth-stage read voltage R8, or the fourteenth-stage read voltage R14. Two-bit binary data corresponding to the middle page, upper page, and extra page is 11, and the binary data corresponding to the middle page, upper page, and extra page is used as the check data, and may skip the reading of the data of the upper page and extra page.

Referring to FIG. 11, in an example, the quad-level cell serves as another multi-level cell for use, and may also read two-bit four-state storage data through 4 stages of read voltages. The binary data corresponding to the middle page is 1010 respectively, and reading the middle page needs the third-stage read voltage R3, the seventh-stage read voltage R7, and the ninth-stage read voltage R9. The binary data corresponding to the upper page is 1100 respectively, and reading the upper page needs the fifth-stage read voltage R5. The binary data corresponding to the lower page is 1011 respectively, the binary data corresponding to the extra page is 1101 respectively, and the binary data corresponding to the lower page and the extra page is used as the check data, and may skip the reading of the data of the upper page and the extra page.

However, a memory cell with high storage density is used as a memory cell with low storage density (excluding using as a single-level cell), for example, the quad-level cell (QLC) serves as the trinary-level cell (TLC) or the multi-level cell (MLC) for use, and read-write efficiency further needs to be improved, for example, how to read storage data to improve read efficiency through fewer stages of read voltages.

In view of this, examples of the present disclosure provide a memory device and an operation method thereof, and a memory system and a storage medium.

In a first aspect, examples of the present disclosure provide a memory device. The memory device comprises: a memory cell array comprising memory cells each storing m data bits, wherein the m data bits correspond to m pages, and each page corresponds to a plurality of stages of read voltages; and a peripheral circuit coupled with the memory cell array and configured to: receive a first read instruction, wherein the first read instruction comprises indicating reading of data on n data bits among the m data bits of the memory cells, wherein m and n both are positive integers, and 1<n<m; and in response to the first read instruction, read data of n pages among the m pages, wherein in the reading process, different pages among the n pages share at least one stage of read voltages, and for a corresponding page of the different pages, an ith memory state and a (i+1)th memory state or a (i−1)th memory state among 2″ memory states corresponding to the n data bits are distinguished through the shared at least one stage of read voltages, wherein i is a positive integer and 1<i<n.

Herein, a structure of the memory device is understood by referring to the aforementioned memory device of FIGS. 1, 2A, 2B, and 6, and is not described herein again.

Herein, a main performing process of the first read instruction may be understood by referring to related descriptions of read operations of FIGS. 7 to 11, and a difference in a detailed performing process lies in that, in the examples of the present disclosure, in the reading process, different pages among the n pages share at least one stage of read voltages, for example, at least one stage of read voltage of a previous read page among the n pages may be used for reading data of a next read page; and the difference in the detailed performing process will be introduced in detail below.

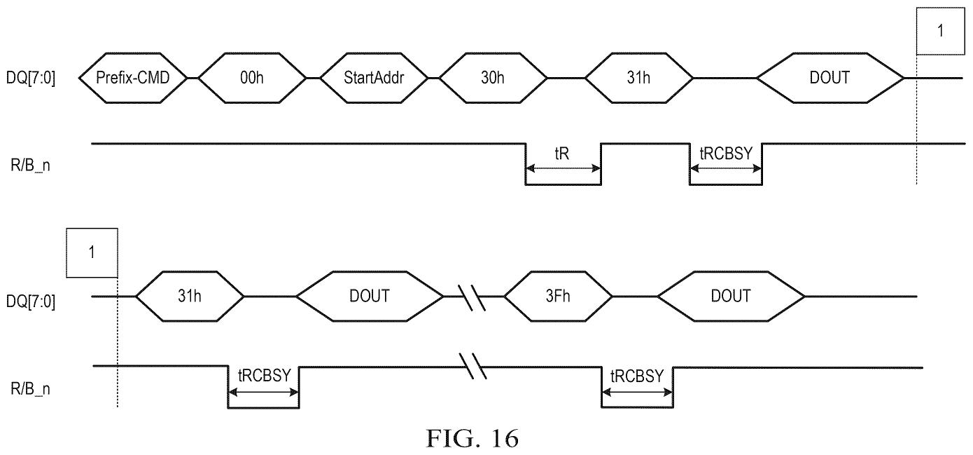

Referring to FIG. 16, in some examples, the first read instruction may be a sequential cache read command.

In some examples, the first read instruction comprises a first prefix command Prefix-CMD, and the peripheral circuit is configured to enter a first read mode according to the first prefix command Prefix-CMD. For example, the first read mode may be a mode in which the QLC serves as the TLC, or may also be a mode in which the QLC serves as the MLC.

In some examples, the peripheral circuit is configured to: in the reading process, skip reading of other pages among the m pages other than the n pages, to sequentially read data of each of the n pages in sequence.

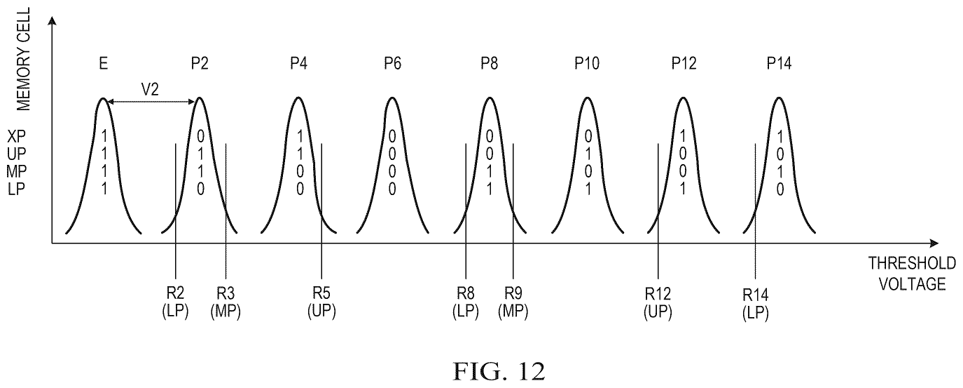

In an example, referring to FIG. 8 or 12, the quad-level cell serves as the trinary-level cell for use, the peripheral circuit is configured to: in the reading process, skip reading of the fourth memory bits XP; and sequentially read data of each page in the first memory bits LP, the second memory bits MP, and the third memory bits UP in sequence.

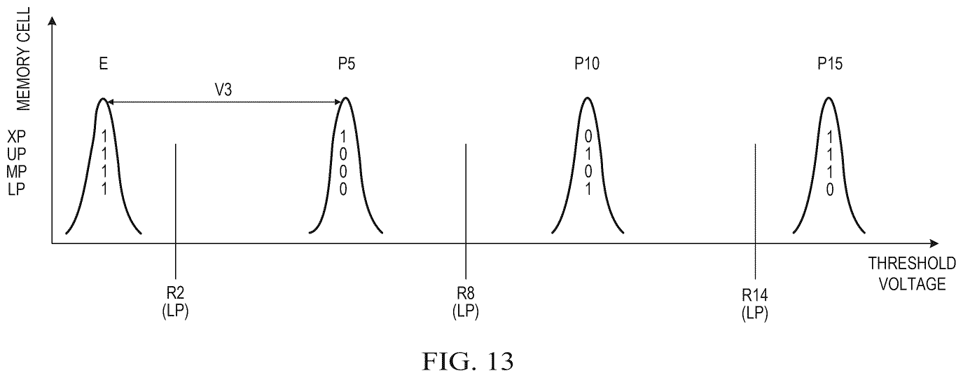

In an example, referring to FIG. 9 or 13, the quad-level cell serves as the multi-level cell for use, the peripheral circuit is configured to: in the reading process, skip the reading of the third memory bits UP and the fourth memory bits XP; and sequentially read the data of each page in the first memory bits LP and the second memory bits MP.

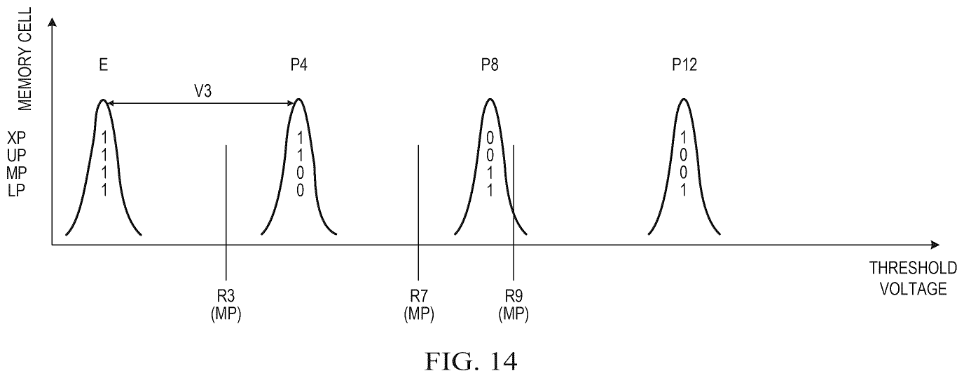

In an example, referring to FIG. 11 or 14, the quad-level cell serves as another multi-level cell for use, the peripheral circuit is configured to: in the reading process, skip the reading of the first memory bits LP and the fourth memory bits XP; and sequentially read the data of each page in the second memory bits MP and the third memory bits UP.

In some examples, the peripheral circuit is configured to: read data of a first page among the n pages through the plurality of stages of read voltages corresponding to the first page; and read at least part of data of a second page among the n pages through part of the plurality of stages of read voltages of the first page.

Here and below, the first page may be understood as a page for storing the valid data, and in a read process, the first page is a page that is the first page to be read among all pages storing the valid data.

In an example, referring to FIG. 8, since the seventh-stage read voltage R7 of the middle page and the eighth-stage read voltage R8 of the lower page fall in a same valley (e.g., between the 6th state P6 and the 8th state P8), the thirteenth-stage read voltage R13 of the middle page and the fourteenth-stage read voltage R14 of the lower page fall in a same valley (e.g., between the 12th state P12 and the 14th state P14), and since the tenth-stage read voltage R10 of the upper page and the ninth-stage read voltage R9 of the middle page fall in a same valley (e.g., between the 8th state P8 and the 10th state P10). In this way, referring to FIGS. 8 and 12, the seventh-stage read voltage R7 of the middle page and the thirteenth-stage read voltage R13 of the middle page may be respectively replaced by the eighth-stage read voltage R8 of the lower page and the fourteenth-stage read voltage R14 of the lower page, and the tenth-stage read voltage R10 of the upper page may be replaced by the ninth-stage read voltage R9 of the middle page.

In an example, referring to FIG. 9, since the third-stage read voltage R3 of the middle page and the second-stage read voltage R2 of the lower page fall in a same valley (e.g., between the 0th state E and the 5th state P5), the thirteenth-stage read voltage R13 of the middle page and the fourteenth-stage read voltage R14 of the lower page fall in a same valley (e.g., between the 10th state P10 and the 15th state P15). In this way, referring to FIGS. 9 and 13, the third-stage read voltage R3 of the middle page and the thirteenth-stage read voltage R13 of the middle page may be respectively replaced by the second-stage read voltage R2 of the lower page and the fourteenth-stage read voltage R14 of the lower page.

In an example, referring to FIG. 11, since the fifth-stage read voltage R5 of the upper page and the seventh-stage read voltage R7 of the middle page fall in a same valley (e.g., between the 4th state and the 8th state). In this way, referring to FIGS. 11 and 14, the fifth-stage read voltage R5 of the upper page may be replaced by the seventh-stage read voltage R7 of the middle page.

In some examples, the memory cell array comprises memory cells each storing four data bits, and the first read instruction comprises indicating reading of data on a first data bit, a second data bit, and a third data bit among the four data bits of the memory cells. The peripheral circuit is configured to: read the data of the first page corresponding to the first data bit through three stages of read voltages corresponding to the first page; read the data of the second page corresponding to the second data bit through part of the three stages of read voltages corresponding to the first page and part of four stages of read voltages corresponding to the second page; and read the data of the third page corresponding to the third data bit through part of the four stages of read voltages corresponding to the second page and part of three stages of read voltages corresponding to the third page.

In an example, referring to FIG. 12, the peripheral circuit may be configured to: read the eight-bit binary data (10001110) corresponding to the lower page through the second-stage read voltage R2, the eighth-stage read voltage R8, and the fourteenth-stage read voltage R14; read the eight-bit binary data (11001001) corresponding to the middle page through the third-stage read voltage R3 and the ninth-stage read voltage R9 of the middle page, and the eighth-stage read voltage R8 and the fourteenth-stage read voltage R14 of the lower page; and read the eight-bit binary data (11100100) corresponding to the upper page through the fifth-stage read voltage R5 and the twelfth-stage read voltage R12 of the upper page, and the ninth-stage read voltage R9 of the middle page. Compared to the fact that storage data of three pages is read through 10 stages of read voltages shown in FIG. 8, in the examples of the present disclosure, the storage data of the three pages is read through 7 stages of read voltages, such that 3 stages of read voltages are reduced, and a sensing time t_{Sensing} is reduced by an average of 1 unit per page. Here and below, 1 unit of the sensing time t_{Sensing} may be understood as the time that is used by sensing storage data of a memory cell under one read voltage from the memory cell to a sensing latch, and then transmitting the same to a data latch by the sensing latch.

In some examples, the memory cell array comprises memory cells each storing four data bits, and the first read instruction comprises indicating reading of data on a first data bit and a second data bit among the four data bits of the memory cells. The peripheral circuit is configured to: read the data of the first page corresponding to the first data bit through three stages of read voltages corresponding to the first page; and read the data of the second page corresponding to the second data bit through one stage of read voltages or two stages of read voltages among the three stages of read voltages corresponding to the first page.

In an example, referring to FIG. 13, the peripheral circuit may be configured to: read the four-bit binary data (1010) corresponding to the lower page through the second-stage read voltage R2, the eighth-stage read voltage R8, and the fourteenth-stage read voltage R14 of the lower page, and obtain the four-bit binary data (1001) corresponding to the middle page through a logical operation based on data that has been read by the second-stage read voltage R2 and the fourteenth-stage read voltage R14 of the lower page. Compared to the fact that storage data of two pages is read through 5 stages of read voltages shown in FIG. 9, in the examples of the present disclosure, the storage data of the two pages is read through 3 stages of read voltages, such that 2 stages of read voltages are reduced, and the sensing time t_{Sensing} is reduced by an average of 1 unit per page.

In an example, referring to FIG. 14, the peripheral circuit is configured to: read the four-bit binary data (1010) corresponding to the middle page through the third-stage read voltage R3, the seventh-stage read voltage R7, and the ninth-stage read voltage R9 of the middle page, and obtain the four-bit binary data (1100) corresponding to the upper page through the logical operation based on data that has been read by the seventh-stage read voltage R7 of the middle page. Compared to the fact that storage data of two pages is read through 4 stages of read voltages shown in FIG. 11, in the examples of the present disclosure, the storage data of the two pages is read through 3 stages of read voltages, such that 1-stage read voltages are reduced, and the sensing time t_{Sensing} is reduced by an average of 0.5 unit per page.

In the examples of the present disclosure, the quad-level cell serves as the multi-level cell for use, e.g., the QLC serves as the MLC for use, and storage data of the MLC is read through the 3 stages of read voltages, read performance reaches a same level as that of a real MLC.

In some examples, the peripheral circuit comprises a page buffer, and the page buffer comprises a cache latch and a plurality of data latches. The peripheral circuit is configured to: perform a first operation, wherein the first operation comprises respectively saving, in the plurality of data latches, three sensing results corresponding to the three stages of read voltages; perform a second operation, wherein the second operation comprises performing a first logical operation on data saved in each of the plurality of data latches to obtain the data of the first page, and saving the data of the first page in the cache latch; and perform a third operation, wherein the third operation comprises performing a second logical operation on data saved in part of the plurality of data latches to obtain the data of the second page, and saving the data of the second page in the cache latch.

Here and below, referring to FIG. 13, example descriptions are performed by using the first page as the lower page, using the second page as the middle page, using the third page as the upper page, and using the fourth page as the extra page. However, that the first page is the lower page, the second page is the middle page, the third page is the upper page, and the fourth page is the extra page is not used to limit various examples of the present disclosure. For example, referring to FIG. 14, the first page may be the middle page, the second page may be the upper page, the third page may be the lower page, and the fourth page may be the extra page.

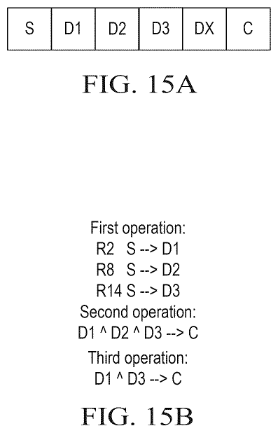

Referring to FIGS. 13 and 15A, in some examples, the page buffer may comprise a cache latch C and four data latches, wherein the four data latches are a first latch D1, a second latch D2, a third latch D3, and a fourth latch DX. The first latch D1, the second latch D2, the third latch D3, and the fourth latch DX may be respectively configured to store the data of the lower page, middle page, upper page, and extra page of the memory device. In some examples, the page buffer further comprises a sensing latch S (also referred to as a read-out latch S), wherein the sensing latch S may store the data of the lower page, middle page, upper page, or extra page that is measured (or read out) from a bit line, and the data of the lower page, middle page, upper page, or extra page that is stored in the sensing latch S is transmitted to the first latch D1, the second latch D2, the third latch D3, or the fourth latch DX, respectively.

Referring to FIGS. 13 and 15B, the quad-level cell serves as the multi-level cell for use, and the peripheral circuit is configured to: in the reading process, skip the reading of the upper page and the extra page, and sequentially read the data of each page in the lower page and the middle page in sequence, wherein when the data of the lower page is read, the first operation and the second operation are performed, and when the data of the middle page is read, only the third operation is performed.

Herein, the first operation comprises: reading the data of the memory cell through the second-stage read voltage R2 of the lower page, storing sensing results in the sensing latch S, and then transmitting the storage data in the sensing latch S to the first latch D1. Likewise, the storage data read by the eighth-stage read voltage R8 of the lower page and the fourteenth-stage read voltage R14 of the lower page may be transmitted to the second latch D2 and the third latch D3 respectively via the sensing latch S.

Herein, the second operation comprises: after performing the logical operation on the storage data of the first latch D1, the second latch D2, and the third latch D3, transmitting the same to the cache latch C, for example, after performing the exclusive OR operation on the storage data of the first latch D1 and the storage data of the second latch D2, performing the exclusive OR operation with the storage data of the third latch D3 to obtain an operation result, and transmitting the operation result to the cache latch C, wherein a logical expression of the operation result is D1\hat{ }D2\hat{ }D3, and the operation result is the four-bit binary data (1010) corresponding to the lower page. That is to say, the first operation and the second operation are performed for acquiring the four-bit binary data (1010) corresponding to the lower page, e.g., a sensing process and a transfer process. The sensing process may be understood as a process of sensing the storage data of the memory cell from a memory cell to the data latch; and the transfer process may be understood as a process of transmitting the storage data in the data latch to the sensing latch.

Herein, the third operation comprises: after performing the logical operation on the storage data of the first latch D1 and the third latch D3, transmitting the same to the cache latch C, for example, performing the exclusive OR operation on the storage data of the first latch D1 and the storage data of the third latch D3 to obtain an operation result, and transmitting the operation result to the cache latch C, wherein a logical expression of the operation result is D1\hat{ }D3, and the operation result is the four-bit binary data (1001) corresponding to the lower page. That is to say, only the third operation is performed for acquiring the four-bit binary data (1001) corresponding to the middle page, e.g., the transfer process, such that the sensing process is omitted.

In the examples of the present disclosure, when the quad-level cell serves as the multi-level cell for use, e.g., the QLC serves as the MLC for use, the read process only needs 3 stages of read voltages, e.g., only 3 units of sensing time are required, which is an average of 1.5 units of sensing time per page, the read performance reaches the same level as that of the real MLC.

In some examples, the first read instruction comprises a first prefix command, a first read command, and a second read command. The peripheral circuit is configured to: enter a first read mode according to the first prefix command, and determining data bits to be read as the first data bit and the second data bit; according to the first read command, determine that the data of the first page and the data of the second page have been cleared in a write cache; and perform the first operation and the second operation according to a page to be read of the second read command being the first page, or perform the third operation according to the page to be read of the second read command being the second page, and after completing the performing of the third operation, skip reading of data of a third page and data of a fourth page.

Here and below, the operations of the first operation, second operation, and third operation may be understood by referring to related descriptions of FIGS. 15A and 15B, and are not described herein again.

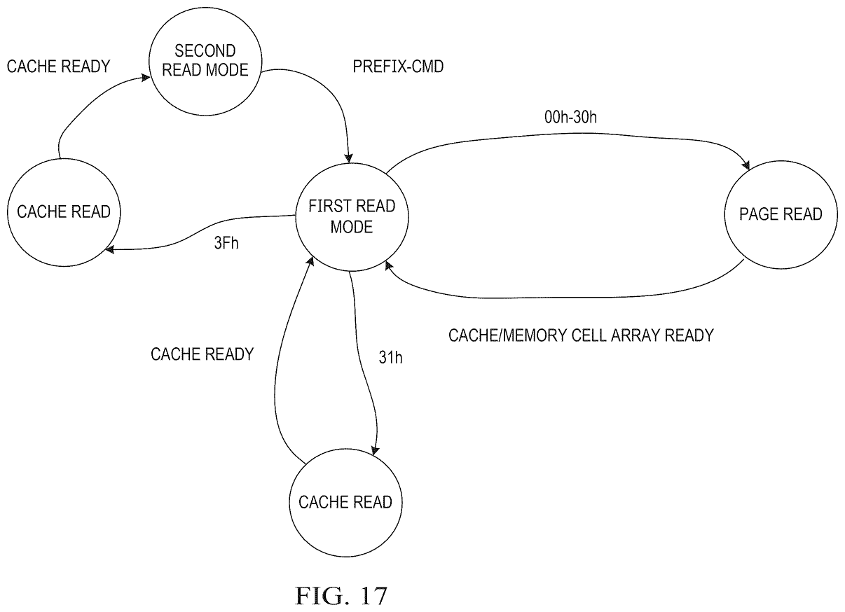

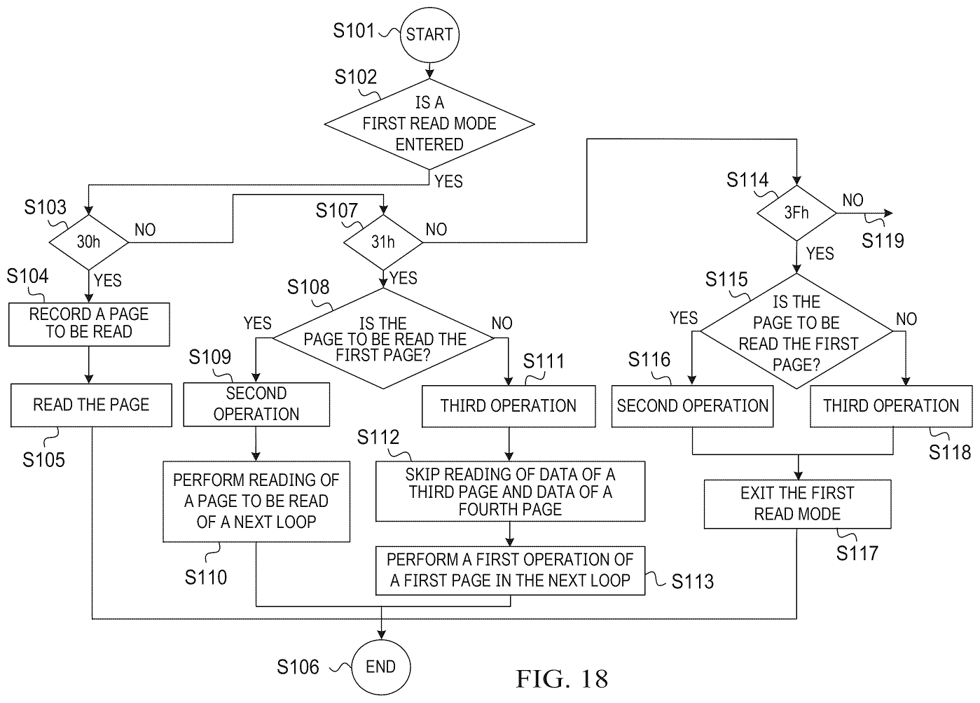

The first read command may be a read cache random command 00h-31h (referring to FIG. 17), or a read cache sequential command 31h (referring to FIG. 18). Here and below, description is performed by using the first read command being the read cache sequential command 31h as an example.

In an example, referring to FIGS. 13, 17, and 18, the peripheral circuit is configured to perform the following operations: S101 and S102, starting reading, and entering, according to the first prefix command Prefix-CMD, the first read mode in which the QLC serves as the MLC for use; S103, according to the first read command 30h, determining that data of a page to be read is not cleared in a write cache; S104, recording the data of the page to be read; S105, reading the recorded data of the page to be read; and S106, ending reading.

In an example, referring to FIGS. 13, 17, and 18, the peripheral circuit is configured to perform the following operations: S101 and S102, starting reading, and entering, according to the first prefix command Prefix-CMD, the first read mode in which the QLC serves as the MLC for use; and S103, according to the first read command 30h, determining that the data of the page to be read has been cleared in the write cache; and reading the data of the lower page and the middle page according to the second read command (comprising operation S108), and after completing the reading of the data of the lower page and the middle page, exiting the first read mode. The peripheral circuit is configured to perform operation S108, comprising: determining whether the page to be read is the lower page; if the page to be read is the lower page, performing the first operation and the second operation; if the page to be read is the middle page (e.g., the page to be read is not the lower page), only performing the third operation; and after the third operation, skipping the reading of the data of the upper page and the data of the extra page.

In some examples, the second read command comprises a sequential read command and a read end command. The peripheral circuit is configured to: perform the second operation according to a page to be read of the sequential read command being the first page, or perform the third operation according to the page to be read of the sequential read command being the second page, and after completing the performing of the third operation, skip the reading of the data of the third page and the data of the fourth page, and perform reading of the first page in a next loop; and perform the second operation according to an end page of the read end command being the first page, and after completing the performing of the second operation, exit the first read mode, or perform the third operation according to the end page of the read end command being the second page, and after completing the performing of the third operation, exit the first read mode.

In an example, referring to FIGS. 13, 17, and 18, the peripheral circuit is configured to perform the following operations: S101 and S102, starting reading, and entering, according to the first prefix command Prefix-CMD, the first read mode in which the QLC serves as the MLC for use; S103, according to the first read command 30h, determining that the data of the page to be read has been cleared in the write cache; S107 and S108, according to the read cache sequential command 31h of the second read command, determining whether the page to be read is the lower page; S109, if the page to be read is the lower page, performing the second operation; S110, after the second operation, performing reading of a page to be read of a next loop; S111, if the page to be read is the middle page (e.g., the page to be read is not the lower page), performing the third operation; S112, after the third operation, skipping the reading of the data of the third page and the data of the four page; S113, after skipping the reading of the data of the third page and the data of the four page, performing the first operation of the first page in the next loop; and S106, ending reading until the data of all pages to be read has been read.

In an example, referring to FIGS. 13, 17, and 18, the peripheral circuit is configured to perform the following operations: S114 and S115, according to the fact that the read cache sequential command 31h has been completed, determining, according to a read end command 3Fh of the second read command, whether the page to be read is the lower page; S116, if the page to be read is the lower page, performing the second operation; S117, after the second operation, exiting the first read mode; S118, if the page to be read is the middle page (e.g., the page to be read is not the lower page), performing the third operation; S117, after the third operation, exiting the first read mode; and S106, ending reading.

In some examples, the peripheral circuit is further configured to: before receiving the first read instruction, receive a first write instruction and data to be written, wherein the first write instruction comprises indicating writing of the data to be written to the n data bits among the m data bits of the memory cells; according to the data to be written, determine dummy data on the remaining data bits among the m data bits other than the n data bits; and write the data to be written and the dummy data to the memory cell array.

Herein, the data to be written may be understood as the aforementioned valid data, and the dummy data may be understood as the aforementioned redundant data or check data.

In an example, referring to FIGS. 7 and 13, when a quad-level cell serves as the multi-level cell for use, the dummy data is determined according to the data to be written, the data to be written is stored in the first memory bits LP and the second memory bits MP, and the dummy data is stored in the third memory bits UP and the fourth memory bits XP. The dummy data is determined according to the data to be written. In an example, the third memory bits UP is obtained by performing the OR operation on the first memory bits LP and the second memory bits MP, and the fourth memory bits XP may be obtained by performing the not operation on the first memory bits LP and then performing the OR operation with the second memory bits MP.

In some examples, the peripheral circuit is further configured to: receive a second read instruction, wherein the second read instruction comprises indicating reading of data on m data bits among the m data bits of the memory cells; enter a second read mode to read m pages of data among the m pages, wherein in the reading process, different pages among the m pages all employ different stages of read voltages; and after the read is completed, exit the second read mode.

In an example, referring to FIGS. 7, 17, and 18, the peripheral circuit is configured to perform the following operations: S119, receiving a second read instruction according to the fact that the read end command 3Fh of the second read command has been completed, so as to enter a second read mode.

The second read mode comprises reading the data of the lower page, middle page, upper page, and extra page in sequence. In an example, the sensing process of the data of the lower page comprises: reading the data of the memory cell through the second-stage read voltage R2 of the lower page, storing sensing results in the sensing latch S, and then transmitting the storage data in the sensing latch S in the first latch D1, and likewise, respectively transmitting the storage data read by the eighth-stage read voltage R8 of the lower page and the fourteenth-stage read voltage R14 of the lower page to the second latch D2 and the third latch D3. In an example, the transfer process of the data of the lower page comprises: after performing the logical operation on the storage data of the first latch D1, the second latch D2, and the third latch D3, transmitting the same to the cache latch C, for example, after performing the exclusive OR operation on the storage data of the first latch D1 and the storage data of the second latch D2, performing the exclusive OR operation with the storage data of the third latch D3 to obtain an operation result, and transmitting the operation result to the cache latch C, wherein a logical expression of the operation result is D1\hat{ }D2\hat{ }D3, and the operation result is the sixteen-bit binary data (1100000011111100) corresponding to the lower page. Referring to the sensing process and transfer process of the data of the lower page, the sixteen-bit binary data corresponding to the middle page may be obtained to be 1110000110000111, the sixteen-bit binary data corresponding to the upper page is 1111100000110001, and the sixteen-bit binary data corresponding to the extra page is 1000110000011111.

In some examples, the peripheral circuit is further configured to: before receiving the second read instruction, receive a second write instruction and data to be written, wherein the second write instruction comprises indicating writing of the data to be written to the m data bits among the m data bits of the memory cells; and write the data to be written to the memory cell array.

In an example, referring to FIG. 7, the data to be written is stored in the first memory bits LP and the second memory bits MP, the third memory bits UP, and the fourth memory bits XP.

In various examples of the present disclosure, a memory cell with high storage density is used as a memory cell with low storage density (excluding using as a single-level cell). For example, a quad-level cell (QLC) serves as a trinary-level cell (TLC) or a multi-level cell (MLC) for use, such that the number of stages of read voltages is simplified, and the number of times of sensing processes is reduced, thereby shortening a read time and improving read efficiency.

In a second aspect, examples of the present disclosure provide a memory system. The memory system comprises: one or more memory devices as provided in any one of the first aspects; and a memory controller coupled to the memory device and configured to control the memory device.

Herein, a structure of the memory system may be understood by referring to the aforementioned related descriptions of FIGS. 1, 2A, 2B, and 6, and is not described herein again.

Herein, a control section of the memory controller may be understood by referring to a processor 1063 of the memory controller 106 in FIG. 6. The processor 1063 is configured to entirely control the memory system 102.

In some examples, the memory system 102 comprises Solid State Drives (SSD), and the memory device comprises a NAND memory.

For example, the solid state drives may be consumer-grade SSDs storing personal information of a user, or may also be enterprise-grade SSDs storing privacy information of a user; and the memory device may comprise an apparatus of a FLASH chip (e.g., a three-dimensional NAND Flash memory). The FLASH chip may be used as a storage medium of the SSD of the above-mentioned memory system 102 to store data.

In a third aspect, examples of the present disclosure provide an operation method of a memory device. The memory device comprises a memory cell array and a peripheral circuit coupled with the memory cell array; the memory cell array comprises memory cells each storing m data bits, the m data bits correspond to m pages, and each page corresponds to a plurality of stages of read voltages. The operation method comprises: receiving a first read instruction, wherein the first read instruction comprises indicating reading of data on n data bits among the m data bits of the memory cells, wherein m and n both are positive integers, and 1<n<m; and in response to the first read instruction, reading data of n pages among the m pages, wherein in the reading process, different pages among the n pages share at least one stage of read voltages, and for a corresponding page of the different pages, an ith memory state and a (i+1)th memory state or a (i−1)th memory state among 2ⁿ memory states corresponding to the n data bits are distinguished through the shared at least one stage of read voltages, wherein i is a positive integer and 1<i<n.

In some examples, the operation method comprises: in the reading process, skipping reading of other pages among the m pages other than the n pages, to sequentially reading data of each of the n pages in sequence.

In some examples, the operation method comprises: reading data of a first page among the n pages through the plurality of stages of read voltages corresponding to the first page; and reading at least part of data of a second page among the n pages through part of the plurality of stages of read voltages of the first page.

In some examples, the memory cell array comprises memory cells each storing four data bits, and the first read instruction comprises indicating reading of data on a first data bit and a second data bit among the four data bits of the memory cells. The operation method comprises: reading the data of the first page corresponding to the first data bit through three stages of read voltages corresponding to the first page; and reading the data of the second page corresponding to the second data bit through one stage of read voltages or two stages of read voltages among the three stages of read voltages corresponding to the first page.

In some examples, the peripheral circuit comprises a page buffer, and the page buffer comprises a cache latch and a plurality of data latches. The operation method comprises: performing a first operation, wherein the first operation comprises respectively saving, in the plurality of data latches, sensing results corresponding to the three stages of read voltages; performing a second operation, wherein the second operation comprises performing a first logical operation on data saved in each of the plurality of data latches to obtain the data of the first page, and saving the data of the first page in the cache latch; and performing a third operation, wherein the third operation comprises performing a second logical operation on data saved in part of the plurality of data latches to obtain the data of the second page, and saving the data of the second page in the cache latch.

In some examples, the first read instruction comprises a first prefix command, a first read command, and a second read command. The operation method comprises: entering a first read mode according to the first prefix command, and determining data bits to be read as the first data bit and the second data bit; according to the first read command, determining that the data of the first page and the data of the second page have been cleared in a write cache; and performing the first operation and the second operation according to a page to be read of the second read command being the first page, or performing the third operation according to the page to be read of the second read command being the second page, and after completing the performing of the third operation, skipping reading of data of a third page and data of a fourth page.

In some examples, the second read command comprises a sequential read command and a read end command. The operation method comprises: performing the second operation according to a page to be read of the sequential read command being the first page, or performing the third operation according to the page to be read of the sequential read command being the second page, after completing the performing of the third operation, skipping the reading of the data of the third page and the data of the fourth page, and performing reading of the first page in a next loop; and performing the second operation according to an end page of the read end command being the first page, and after completing the performing of the second operation, exiting the first read mode, or performing the third operation according to the end page of the read end command being the second page, and after completing the performing of the third operation, exiting the first read mode.

In some examples, the memory cell array comprises memory cells each storing four data bits, and the first read instruction comprises indicating reading of data on a first data bit, a second data bit, and a third data bit among the four data bits of the memory cells. The operation method comprises: reading the data of the first page corresponding to the first data bit through three stages of read voltages corresponding to the first page; reading the data of the second page corresponding to the second data bit through part of the three stages of read voltages corresponding to the first page and part of four stages of read voltages corresponding to the second page; and reading the data of the third page corresponding to the third data bit through part of the four stages of read voltages corresponding to the second page and part of three stages of read voltages corresponding to the third page.

In some examples, the operation method further comprises: before receiving the first read instruction, receiving a first write instruction and data to be written, wherein the first write instruction comprises indicating writing of the data to be written to the n data bits among the m data bits of the memory cells; according to the data to be written, determining dummy data on the remaining data bits among the m data bits other than the n data bits; and writing the data to be written and the dummy data to the memory cell array.

In some examples, the operation method further comprises: receiving a second read instruction, wherein the second read instruction comprises indicating reading of data on m data bits among the m data bits of the memory cells; entering a second read mode to read m pages of data among the m pages, wherein in the reading process, different pages among the m pages all employ different stages of read voltages; and after the read is completed, exiting the second read mode.

The memory device utilized by the operation method of a memory device provided in the examples of the present disclosure is the same as or similar to the above-mentioned memory device in various examples of the first aspect. Technical features that are not disclosed in detail in the examples of the present disclosure are understood by referring to the above-mentioned memory device in various examples of the first aspect, and are not described herein again.

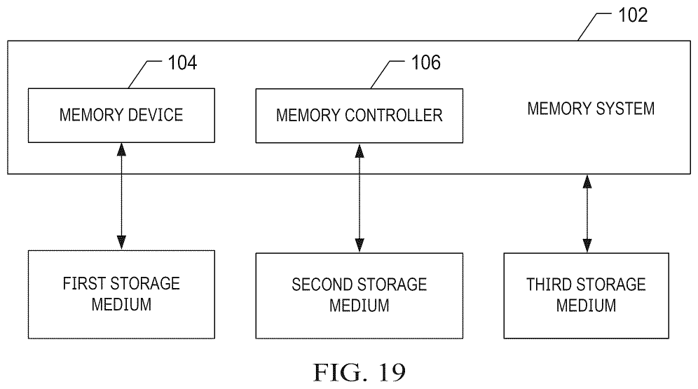

In a fourth aspect, examples of the present disclosure provide a storage medium. Referring to FIG. 19, the storage medium stores executable instructions, and when the executable instructions are executed, operations of any one of the operation methods as provided in the third aspect are implemented.

In some examples, the storage medium may be a ferromagnetic random access memory (FRAM), a read only memory (ROM), a programmable read-only memory (PROM), an erasable programmable read-only memory (EPROM), an electrically erasable programmable read-only memory (EEPROM), a flash memory, a magnetic surface memory, an optical disk, or a CD-ROM (Compact Disc Read-Only Memory) and other memories, or various apparatuses comprising one or any combination of the above memory devices.

In some examples, a computer program may be written in any form of programming language (comprising a compiled or interpreted language, or a declarative or procedural language) by adopting a form of a program, software, a software module, a script or codes; and it may be deployed in any form, comprising deployed as an independent program or as a module, a component, a subroutine, or other units suitable for use in a computing environment.

As an example, executable instructions may, but do not necessarily, correspond to files in a file system, may be stored in part of a file storing other programs or data, for example, stored in one or more scripts in a hyper text markup language (HTML) document, stored in single file dedicated for the discussed program, or stored in a plurality of cooperative files (e.g., files for storing one or more modules, subprograms or code portions).

As an example, a computer program may be deployed on an electronic apparatus for performing, or on a plurality of electronic apparatuses at one location for performing, or distributed on a plurality of electronic apparatuses interconnected through a communication network at a plurality of locations for performing.

In some examples, referring to FIG. 19, FIG. 19 is a schematic diagram of a composition structure of a storage medium provided by examples of the present disclosure. The storage medium comprises a first storage medium corresponding to the memory device 104, a second storage medium corresponding to the memory controller 106, and a third storage medium corresponding to the memory system 102. When the computer program is performed by the memory device, the first storage medium may be configured to implement operations of the operation method of a memory device in the above-mentioned examples of the present disclosure; when the computer program is performed by the memory controller 106, the second storage medium may be configured to implement operations of an operation method of a memory controller 106; and when the computer program is performed by the memory system 102, the third storage medium may be configured to implement operations of an operation method of a memory system 102.

It is to be understood that “one example” and “an example” mentioned in the whole specification mean that features, structures or characteristics related to the example is included in at least one example of the present disclosure. Therefore, “in one example” or “in an example” appearing at various places in the whole specification does not always refer to the same example. In addition, these features, structures or characteristics may be combined in one or more examples in any proper manner. It is to be understood that, in various examples of the present disclosure, sequence numbers of the above processes do not indicate an execution sequence, and an execution sequence of various processes shall be determined by functionalities and intrinsic logic thereof, and shall constitute no limitation on an implementation process of the examples of the present disclosure. The above sequence numbers of the examples of the present disclosure are only for description, and do not represent goodness and badness of the examples.

The above descriptions are merely preferred implementations of the present disclosure, and not intended to limit the patent scope of the present disclosure. Equivalent structural transformation made within using the contents of the specification and the drawings of the present disclosure under the inventive concept of the present disclosure, or direct/indirect application to other related technical fields are both encompassed within the patent protection scope of the present disclosure.

What is claimed is:

1. A memory device, comprising:
a memory cell array comprising memory cells each storing m data bits, wherein the m data bits correspond to m pages, and each page corresponds to a plurality of stages of read voltages; and
a peripheral circuit coupled with the memory cell array and configured to:
receive a first read instruction, wherein the first read instruction comprises indicating reading of data on n data bits among the m data bits of the memory cells, wherein m and n both are positive integers, and 1<n<m; and
in response to the first read instruction, read data of n pages among the m pages, wherein in a reading process, different pages among the n pages share at least one stage of read voltages, and for a corresponding page of the different pages, an ith memory state and a (i+1)th memory state or a (i−1)th memory state among 2ⁿ memory states corresponding to the n data bits are distinguished through the shared at least one stage of read voltages, wherein i is a positive integer and 1<i<n.

2. The memory device of claim 1, wherein the peripheral circuit is configured to:
in the reading process, skip reading of other pages among the m pages other than the n pages, to sequentially read data of each of the n pages in sequence.

3. The memory device of claim 1, wherein the peripheral circuit is configured to:
read data of a first page among the n pages through the plurality of stages of read voltages corresponding to the first page; and
read at least part of data of a second page among the n pages through part of the plurality of stages of read voltages of the first page.

4. The memory device of claim 3, wherein the memory cell array comprises memory cells each storing four data bits, and the first read instruction comprises indicating reading of data on a first data bit and a second data bit among the four data bits of the memory cells; and
the peripheral circuit is configured to:
read the data of the first page corresponding to the first data bit through three stages of read voltages corresponding to the first page; and
read the data of the second page corresponding to the second data bit through one stage of read voltages or two stages of read voltages among the three stages of read voltages corresponding to the first page.

5. The memory device of claim 4, wherein the peripheral circuit comprises a page buffer, and the page buffer comprises a cache latch and a plurality of data latches; and
the peripheral circuit is configured to:
perform a first operation, wherein the first operation comprises respectively saving, in the plurality of data latches, three sensing results corresponding to the three stages of read voltages;
perform a second operation, wherein the second operation comprises performing a first logical operation on data saved in each of the plurality of data latches to obtain the data of the first page, and saving the data of the first page in the cache latch; and
perform a third operation, wherein the third operation comprises performing a second logical operation on data saved in part of the plurality of data latches to obtain the data of the second page, and saving the data of the second page in the cache latch.

6. The memory device of claim 5, wherein the first read instruction comprises a first prefix command, a first read command, and a second read command; and the peripheral circuit is configured to:
enter a first read mode according to the first prefix command, and determine data bits to be read as the first data bit and the second data bit;
according to the first read command, determine that the data of the first page and the data of the second page have been cleared in a write cache; and
perform the first operation and the second operation according to a page to be read of the second read command being the first page, or perform the third operation according to the page to be read of the second read command being the second page, and after completing the performing of the third operation, skip reading of data of a third page and data of a fourth page.

7. The memory device of claim 6, wherein the second read command comprises a sequential read command and a read end command; and the peripheral circuit is configured to:
perform the second operation according to a page to be read of the sequential read command being the first page, or perform the third operation according to the page to be read of the sequential read command being the second page, and after completing the performing of the third operation, skip the reading of the data of the third page and the data of the fourth page, and perform reading of the first page in a next loop; and
perform the second operation according to an end page of the read end command being the first page, and after completing the performing of the second operation, exit the first read mode; or perform the third operation according to the end page of the read end command being the second page, and after completing the performing of the third operation, exit the first read mode.

8. The memory device of claim 3, wherein the memory cell array comprises memory cells each storing four data bits, and the first read instruction comprises indicating reading of data on a first data bit, a second data bit, and a third data bit among the four data bits of the memory cells; and
the peripheral circuit is configured to:
read the data of the first page corresponding to the first data bit through three stages of read voltages corresponding to the first page;
read the data of the second page corresponding to the second data bit through part of the three stages of read voltages corresponding to the first page and part of four stages of read voltages corresponding to the second page; and
read the data of a third page corresponding to the third data bit through part of the four stages of read voltages corresponding to the second page and part of three stages of read voltages corresponding to the third page.

9. The memory device of claim 1, wherein the peripheral circuit is further configured to:
before receiving the first read instruction, receive a first write instruction and data to be written, wherein the first write instruction comprises indicating writing of the data to be written to the n data bits among the m data bits of the memory cells;
according to the data to be written, determine dummy data on the remaining data bits among the m data bits other than the n data bits; and
write the data to be written and the dummy data to the memory cell array.

10. The memory device of claim 1, wherein the peripheral circuit is further configured to:
receive a second read instruction, wherein the second read instruction comprises indicating reading of data on m data bits among the m data bits of the memory cells;
enter a second read mode to read m pages of data among the m pages, wherein in the reading process, different pages among the m pages all employ different stages of read voltages; and after the read is completed, exit the second read mode.

11. A memory system, comprising:
one or more memory devices, each comprising:
a memory cell array comprising memory cells each storing m data bits, wherein the m data bits correspond to m pages, and each page corresponds to a plurality of stages of read voltages; and
a peripheral circuit coupled with the memory cell array and configured to:
receive a first read instruction, wherein the first read instruction comprises indicating reading of data on n data bits among the m data bits of the memory cells, wherein m and n both are positive integers, and 1<n<m; and
in response to the first read instruction, read data of n pages among the m pages, wherein in a reading process, different pages among the n pages share at least one stage of read voltages, and for a corresponding page of the different pages, an ith memory state and a (i+1)th memory state or a (i−1)th memory state among 2ⁿ memory states corresponding to the n data bits are distinguished through the shared at least one stage of read voltages, wherein i is a positive integer and 1<i<n; and
a memory controller coupled to the memory devices and configured to control the memory devices.

12. The memory system of claim 11, comprising a solid state disk, wherein the memory device comprises a NAND memory.

13. An operation method of a memory device, wherein the memory device comprises a memory cell array and a peripheral circuit coupled with the memory cell array; the memory cell array comprises memory cells each storing m data bits, the m data bits correspond to m pages, and each page corresponds to a plurality of stages of read voltages; and
the operation method comprises:
receiving a first read instruction, wherein the first read instruction comprises indicating reading of data on n data bits among the m data bits of the memory cells, wherein m and n both are positive integers, and 1<n<m; and
in response to the first read instruction, reading data of n pages among the m pages, wherein in a reading process, different pages among the n pages share at least one stage of read voltages, and for a corresponding page of the different pages, an ith memory state and a (i+1)th memory state or a (i−1)th memory state among 2″ memory states corresponding to the n data bits are distinguished through the shared at least one stage of read voltages, wherein i is a positive integer and 1<i<n.

14. The operation method of claim 13, comprising:
in the reading process, skipping reading of other pages among the m pages other than the n pages, to sequentially reading data of each of the n pages in sequence;
before receiving the first read instruction, receiving a first write instruction and data to be written, wherein the first write instruction comprises indicating writing of the data to be written to the n data bits among the m data bits of the memory cells;
according to the data to be written, determining dummy data on the remaining data bits among the m data bits other than the n data bits; and
writing the data to be written and the dummy data to the memory cell array.

15. The operation method of claim 13, comprising:
reading data of a first page among the n pages through the plurality of stages of read voltages corresponding to the first page; and
reading at least part of data of a second page among the n pages through part of the plurality of stages of read voltages of the first page.

16. The operation method of claim 15, wherein the memory cell array comprises memory cells each storing four data bits, and the first read instruction comprises indicating reading of data on a first data bit and a second data bit among the four data bits of the memory cells; and
the operation method comprises:
reading the data of the first page corresponding to the first data bit through three stages of read voltages corresponding to the first page; and
reading the data of the second page corresponding to the second data bit through one stage of read voltages or two stages of read voltages among the three stages of read voltages corresponding to the first page.

17. The operation method of claim 16, wherein the peripheral circuit comprises a page buffer, and the page buffer comprises a cache latch and a plurality of data latches; and
the operation method comprises:
performing a first operation, wherein the first operation comprises respectively saving, in the plurality of data latches, sensing results corresponding to the three stages of read voltages;
performing a second operation, wherein the second operation comprises performing a first logical operation on data saved in each of the plurality of data latches to obtain the data of the first page, and saving the data of the first page in the cache latch; and
performing a third operation, wherein the third operation comprises performing a second logical operation on data saved in part of the plurality of data latches to obtain the data of the second page, and saving the data of the second page in the cache latch.

18. The operation method of claim 17, wherein the first read instruction comprises a first prefix command, a first read command, and a second read command; and the operation method comprises:
entering a first read mode according to the first prefix command, and determining data bits to be read as the first data bit and the second data bit;
according to the first read command, determining that the data of the first page and the data of the second page have been cleared in a write cache; and
performing the first operation and the second operation according to a page to be read of the second read command being the first page, or performing the third operation according to the page to be read of the second read command being the second page, and after completing the performing of the third operation, skipping reading of data of a third page and data of a fourth page.

19. The operation method of claim 18, wherein the second read command comprises a sequential read command and a read end command; and the operation method comprises:
performing the second operation according to a page to be read of the sequential read command being the first page, or performing the third operation according to the page to be read of the sequential read command being the second page, after completing the performing of the third operation, skipping the reading of the data of the third page and the data of the fourth page, and performing reading of the first page in a next loop; and
performing the second operation according to an end page of the read end command being the first page, and after completing the performing of the second operation, exiting the first read mode, or performing the third operation according to the end page of the read end command being the second page, and after completing the performing of the third operation, exiting the first read mode.

20. The operation method of claim 15, wherein the memory cell array comprises memory cells each storing four data bits, and the first read instruction comprises indicating reading of data on a first data bit, a second data bit, and a third data bit among the four data bits of the memory cells; and
the operation method comprises:
reading the data of the first page corresponding to the first data bit through three stages of read voltages corresponding to the first page;
reading the data of the second page corresponding to the second data bit through part of the three stages of read voltages corresponding to the first page and part of four stages of read voltages corresponding to the second page; and
reading the data of a third page corresponding to the third data bit through part of the four stages of read voltages corresponding to the second page and part of three stages of read voltages corresponding to the third page.
